(19) United States
(12) Patent Application Publication
(10) Pub. No.: US 2005/0026455 A1
(43) Pub. Date: Feb. 3, 2005

(54) Substrate processing apparatus and substrate processing method

(76) Inventors: Satomi Hamada, Kanagawa-ken (JP); Michihisa Kono, Tokyo (JP); Ichiro Katakabe, Kanagawa-Ken (JP); Shohei Shima, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 10/854,281

(22) Filed: May 27, 2004

(30) Foreign Application Priority Data
May 30, 2003 (JP) 2003-154810
May 19, 2004 (JP) 2004-149628
May 19, 2004 (JP) 2004-149629

(51) Int. Cl. C23F 1/00; H01L 21/31

(52) U.S. Cl. 438/782; 156/345.11; 156/345.15

(57) ABSTRACT

The present invention provides a substrate processing apparatus having a drying mechanism for removing water from the surface of a substrate which has been cleaned by a wet cleaning process, and a substrate processing apparatus and a substrate processing method which are capable of efficiently removing an unnecessary thin film deposited on or adhering to a bevel or edge portion of a substrate. The substrate processing apparatus of this invention has a substrate holder for holding a substrate, and a dry gas supply section for turning an atmosphere to which at least a portion of a surface of the substrate held by the substrate holder is exposed into a humidity-controlled dry gas atmosphere.

### BACKGROUND OF THE INVENTION

1. Field of the Invention

The present invention relates to a substrate processing apparatus and a substrate processing method, and more particularly to a substrate processing apparatus having a drying mechanism for removing water from a surface of a substrate which has been cleaned by a wet cleaning process, and a substrate processing apparatus and a substrate processing method which are capable of efficiently removing an unnecessary thin film deposited on or adhering to a bevel or edge portion of a substrate.

The present invention is also concerned with a substrate processing apparatus and a substrate processing method which can suppress the formation of water marks on a substrate.

2. Description of the Related Art

In each of processing processes performed for the fabrication of semiconductor devices, it is widely practiced to process a substrate such as a semiconductor wafer or the like, and thereafter clean the substrate in a wet cleaning process wherein the substrate is dried in a final stage for the purpose of completely removing water from a surface of the substrate. For drying the substrate, a spin-drying for rotating the substrate at a high speed to remove water on the substrate under centrifugal forces is in widespread use as a general drying process.

As substrates such as semiconductor wafers or the like have larger diameters, the mainstream process of cleaning and drying substrates is shifting from the conventional batch process toward a substrate-by-substrate processing process. Substrate processing apparatus for performing such a substrate-by-substrate cleaning and drying process generally have a substrate holder for holding the substrate substantially horizontally and a rotation drive mechanism for rotating the substrate holder at a high speed. According to the substrate processing process performed by the substrate processing apparatus, the surface of the substrate is supplied with a chemical liquid while the substrate is being rotated to perform a chemical liquid processing process, and thereafter the substrate is supplied with a cleaning liquid such as pure water (DIW) or the like to perform a cleaning process (rinsing process). Since DIW or the like as the cleaning liquid remains attached to the surface of the substrate after the cleaning process, a drying process (spin-drying process) for rotating the substrate at a high speed is performed to remove the DIW or the like.

In the chemical liquid cleaning process or rinsing process based on the substrate-by-substrate spinning principles, the rotational speed of the substrate is often set to about several hundred rpm in order to spread the chemical liquid or DIW (treatment liquid) fully over the entire surface of the substrate. In the following drying process, the rotational speed of the substrate is often set to a high speed in the range from 1000 rpm to 4000 rpm in order to quickly remove not only visible liquid droplets adhering to the substrate, but also small liquid droplets having submicron diameters.

FIG. 1 shows an example of a profile of rotational speeds of a substrate in a conventional substrate processing process. In the graph shown in FIG. 1, the horizontal axis represents time (seconds) that elapses from the start of a substrate drying process, and the vertical axis a substrate rotational speed (rpm). The variables on the horizontal and vertical axes remain the same in figures showing profiles of substrate rotational speeds in other substrate processing processes. According to the profile of substrate rotational speeds shown in FIG. 1, in a chemical processing process and a cleaning process, the substrate rotational speed is set to 500 rpm, and, in a drying process, the substrate rotational speed sharply increases from 500 rpm at the start of the drying process to a maximum rotational speed of 2500 rpm at a rotational acceleration of 1000 rpm/s (about 16.7 sec⁻²).

A silicon surface of a substrate or a surface of a low-k film after it has been processed by HF or the like is a hydrophobic surface. Droplets of a substrate processing liquid that has been scattered from the substrate while the substrate is being spin-dried impinge upon an inner wall of a scattering prevention cup or the like that is disposed around the substrate, and are broken up into a mist. The mist is then scattered over and adheres again to the hydrophobic surface, tending to form so-called water marks which are made of a silicon oxide. Particularly at the start of the substrate drying process, since a large amount of substrate processing liquid remains on the substrate surface, when the substrate rotational speed is sharply increased, the large amount of substrate processing liquid is expelled off under centrifugal forces, causing the production of a large number of water marks.

According to the conventional substrate drying process, as shown in FIG. 1, inasmuch as the substrate is accelerated such that the substrate rotational speed is quickly increased when the substrate cleaning process is finished and changes to the substrate drying process, it is not possible to prevent water marks from occurring. To solve the above problem, there has been proposed a substrate drying process for rotating a substrate at a relatively low speed to remove most of a liquid adhering to the surface of the substrate without much splashing of liquid droplets, and thereafter rotating the substrate at a high speed to remove small droplets from the substrate (see, for example, Japanese laid-open patent publication No. 2003-92280).

In a semiconductor device fabrication process, a thin film is formed on a surface of a substrate generally by sputtering, CVD (Chemical Vapor Deposition), or plating. When a thin film is formed on a surface of a substrate by one of these processes, the thin film is generally deposited on the entire surface of the substrate. However, the thin film needs to be formed only in one surface of the substrate, such as a semiconductor wafer or the like, particularly only in a circuit forming portion on that surface. If the thin film is formed on the entire surface of the substrate or on a bevel or edge portion of the substrate which does not require the thin film thereon, then when the substrate is transferred, for example, the thin film tends to adhere to another substrate by a transfer robot hand, or the thin film tends to be peeled off the substrate and spread around, causing so-called cross-contamination that contaminates the processing environment in other processes. In the substrate fabrication process, therefore, the formation of the thin film is followed by a process for removing the unnecessary thin film.

The unnecessary thin film deposited on or adhering to the bevel or edge portion of the substrate is generally been removed by an etching process for supplying the bevel or edge portion of the substrate with an etching liquid (chemical liquid) to selectively etch away the thin film, or a polishing process for pressing a polishing tool against the bevel or edge portion of the substrate to polish away the thin film.

According to the conventional spin-drying process, it is difficult to remove water droplets having micron to submicron diameters or smaller diameters from the substrate. Particularly, hydrophobic surfaces produced after being processed by a fluoric acid solution or surfaces having fine patterns thereon tend to form water marks due to oxidization only in those spots where such water droplets remain attached, and have their device (forming) areas modified.

As described above, when the rotational acceleration is increased at the time the rotational speed of the substrate changes from a low speed to a high speed in the substrate drying process, since the rotational speed sharply rises, a large amount of liquid is expelled off under centrifugal forces, tending to produce a large number of water marks. If the rotational speed of the substrate is low in the low speed range in the substrate drying process, the liquid that adheres to the surface of the substrate in the low rotational speed stage cannot sufficiently be removed. When the substrate is quickly accelerated from the low rotational speed to the high rotational speed, the substrate reaches the high rotational speed while the liquid remaining on the surface of the substrate is not being sufficiently removed. Therefore, the remaining liquid is expelled off under intensive centrifugal forces and splashed back to form water marks.

On often hydrophobic materials having low dielectric constants or surfaces having a mixture of hydrophilic and hydrophobic properties, in particular, the formation of water marks is so prominent that they give rise to a large problem in the fabrication process.

The problem of liquid splashing does not occur if the substrate is dried by a vacuum drying process which is one of the drying processes other than the spin-drying process. However, the vacuum drying process requires the drying apparatus to be hermetically sealed, and needs ancillary devices such as a vacuum pump separately. Furthermore, only drying the substrate with heat makes the drying process time-consuming, and may possibly deform films that have been formed on the substrate.

The atmosphere in the apparatus should desirably be kept in a comparatively dry state. However, since a mist floats in the atmosphere due to successive processing of substrates and wets the inside of the apparatus, the humidity is liable to increase in the atmosphere. Sufficient air is supplied to and discharged from the apparatus in order to prevent the humidity from increasing in the atmosphere. Because an amount of supplied and discharged air is usually constant, if humidity variations are to be reduced, then it is necessary to make adjustments to set the amount of supplied and discharged air to a higher level in advance or to process substrates at increased intervals, resulting in a loss of time and energy. Furthermore, inasmuch as the temperature and humidity of a supplied gas as well as the amount of discharged air are constant, it is difficult to prevent water marks from being produced owing to an abrupt increase in the humidity from pre-processing.

For removing the unnecessary thin film deposited on or adhering to the bevel or edge portion of the substrate according to an etching process using a chemical liquid, it is desired that the gradient of an edge profile at the outer circumferential end of the thin film which remains unremoved on the substrate by etching be large in order to reduce the width across which to remove the thin film. According to the etching process, however, the edge profile of the thin film cannot have a sharp gradient due to the wettability of the thin film, and there is currently a certain limitation on efforts to reduce the width across which to remove the thin film. Since the etching ability of the chemical liquid is limited, a long processing time is required for removing a hard film such as a silicon nitride film (Si₂N₄) or a tantalum oxide film (Ta₂O₅) that is used as an insulating film having a high dielectric constant, for example.

The process of polishing away the thin film can provide a steep edge profile of the film in a shorter period of time than the etching process and can remove a hard film relatively easily. However, the bevel or edge portion of the substrate tends to have large surface roughness after the polishing process.

### SUMMARY OF THE INVENTION

The present invention has been made in view of the above drawbacks. It is a first object of the present invention to provide a substrate processing apparatus which is capable of quickly and reliably drying a substrate in a drying process that is carried out after a wet cleaning process, and to provide a substrate processing apparatus and a substrate processing method which are capable of removing, in a short period of time, an unnecessary thin film deposited on or adhering to a bevel or edge portion of a substrate, even if the thin film is a hard film, while providing an edge profile having a sharp gradient, and reducing the surface roughness of the bevel or edge portion after the unnecessary thin film has been removed therefrom.

A second object of the present invention is to provide a substrate processing method and a substrate processing apparatus which are capable of preventing liquid droplets from splashing onto the surface of a substrate to suppress the formation of water marks.

To achieve the above objects, a substrate processing apparatus according to the present invention has a substrate holder for holding a substrate, and a dry gas supply section for turning an atmosphere to which at least a portion of a surface of the substrate held by the substrate holder is exposed into a humidity-controlled dry gas atmosphere.

Since an atmosphere to which at least a portion of a surface of the substrate held by the substrate holder is exposed is turned into a humidity-controlled dry gas atmosphere, even if the surface of the substrate is hydrophobic or has fine patterns formed thereon, water droplets remaining on the substrate after a wet cleaning process can quickly be dried off by the humidity-controlled dry gas, preventing a defect referred to as water marks from being produced on the surface of the substrate and also preventing its device (to be formed) areas from being modified.

The substrate holder is preferably rotatable. This makes it possible to apply the present invention to a substrate processing apparatus which performs a spin drying process after the wet cleaning process.

The dry gas supply section is preferably adapted to apply and supply a humidity-controlled dry gas to at least a portion of a surface of the substrate held by the substrate holder.

The dry gas supply section is preferably adapted to supply a dry gas comprising an inactive gas or air having a relative humidity controlled in the range from 0 to 30% into a processing chamber which accommodates the substrate holder therein.

If an inactive gas, e.g., an Ar gas, an N₂ gas, or the like or inexpensive air, whose relative humidity is controlled in the range from 0 to 30%, is used as the dry gas, the substrate can efficiently be dried to suppress the formation of water marks.

The dry gas supply section is preferably adapted to supply a dry gas into the processing chamber, in a volume which is 0.5 to 3 times the total volume of air that is discharged from the processing chamber when the dry gas is supplied from the dry gas supply section into the processing chamber.

With the above arrangement, a sufficient volume of dry gas large enough to dry the substrate can be maintained.

Another substrate processing apparatus according to the present invention has a polishing apparatus for polishing a thin film deposited on or adhering to a bevel or edge portion of a substrate, and an etching apparatus for etching away a thin film remaining on the bevel or edge portion of the substrate which has been polished by the polishing apparatus.

A thin film deposited on or adhering to the bevel or edge portion of the substrate is first polished away by the polishing apparatus. Even if the thin film comprises a hard film such as a silicon nitride film (Si₂N₄) or a tantalum oxide film (Ta₂O₅), it can be removed within a short period of time while providing a steep edge profile. Thereafter, a thin film remaining on the bevel or edge portion is completely etched away by the etching apparatus, so that any surface roughness of the bevel or edge portion is held to a small level.

At least one of the polishing apparatus and the etching apparatus preferably comprises a substrate holder for holding a substrate, and a dry gas supply section for turning an atmosphere to which at least a portion of a surface of the substrate held by the substrate holder is exposed into a humidity-controlled dry gas atmosphere.

With the above arrangement, the substrate is subjected to a wet cleaning process after the polishing process and/or etching process, and water droplets remaining on the cleaned substrate are quickly dried by the humidity-controlled dry gas.

According to a preferred aspect of the present invention, the substrate processing apparatus further comprises a cleaning/drying apparatus for cleaning and drying the substrate whose bevel or edge portion has been etched by the etching apparatus, the cleaning/drying apparatus comprising a substrate holder for holding a substrate, and a dry gas supply section for turning an atmosphere to which at least a portion of a surface of the substrate held by the substrate holder is exposed into a humidity-controlled dry gas atmosphere.

With the above arrangement, water droplets remaining on the cleaned substrate are quickly dried by the humidity-controlled dry gas in the cleaning/drying apparatus.

A substrate processing method according to the present invention comprises polishing away a thin film deposited on or adhering to a bevel or edge portion of a substrate, and etching away a thin film remaining on the bevel or edge portion of the substrate which has been polished.

It is preferable to clean and dry the substrate in which the thin film remaining on the bevel or edge portion thereof has been etched away.

Another substrate processing apparatus according to the present invention comprises a substrate holder for holding a substrate, a monitor for monitoring the degree of drying of the substrate held by the substrate holder, and a controller for controlling rotation of the substrate holder based on a monitor value outputted from the monitor and representing the degree of drying of the substrate.

The degree of drying of the substrate held by the substrate holder is monitored by the monitor, and the rotation of the substrate, e.g., the rotational speed and/or the rotational acceleration, of the substrate is controlled based on the monitored value, for thereby rotating and drying the substrate while the amount of liquid droplets scattered around from the substrate holder and the substrate is small. Therefore, the liquid removed from the substrate is prevented from splashing back to suppress the formation of water marks or the like.

Preferably, the monitor comprises at least one of a mass meter for measuring a mass of liquid droplets scattered around from the substrate when the substrate is dried, a thermometer for measuring a temperature around the substrate, a mist amount measuring instrument for measuring an amount of mist around the substrate, a liquid droplet adhering area measuring mechanism for measuring an area of a liquid droplet adhering portion of the surface of the substrate, and a mass meter for measuring a mass of the substrate and the substrate holder. A measured value or a change in the measured value of at least one of the mass of liquid droplets, the humidity, the amount of mist, the area of the liquid droplet adhering portion of the surface of the substrate, and the mass of the substrate and the substrate holder is fed back to the controller to enable the controller to control the rotation of the substrate holder so that the measured value or the change in the measured value is equal to or less than a constant value.

Still another substrate processing apparatus according to the present invention comprises a substrate holder for holding a substrate, and a controller for accelerating and decelerating a rotational speed of the substrate holder continuously or stepwise.

For example, the substrate holder is rotated together with the substrate at a rotational speed low enough to reduce the amount of a liquid on the substrate and reduce liquid splashing. Subsequently, the rotational speed of the substrate is increased stepwise or continuously to further reduce the amount of the liquid on the substrate. Thus, a large amount of liquid is prevented from being expelled from the substrate under centrifugal forces, thereby avoiding water marks and drying the substrate quickly.

According to a preferred aspect of the present invention, the controller increases the rotational speed of the substrate holder as a linear, quadratic, or higher-order function of a time that has elapsed from the start of drying the substrate at a rotational acceleration in the range from 0 to 300 rpm/s until the rotational speed of the substrate holder reaches a maximum rotational speed.

With the above arrangement, the liquid adhering to the substrate can be removed without being scattered around while the rotational speed of the substrate is being slowly and gradually increased from a low rotational speed at a low rotational acceleration.

According to a preferred aspect of the present invention, the controller changes the rotational speed of the substrate holder in n steps until the rotational speed of the substrate holder changes from an initial rotational speed at the start of drying the substrate to a maximum rotational speed, accelerates the substrate holder at a kth rotational acceleration until the rotational speed thereof changes from a (k-1)th (2≦k≦n) rotational speed to a kth rotational speed, makes the kth rotational speed greater than the (k-1)th rotational speed, and makes the kth rotational acceleration greater than a (k-1)th rotational acceleration.

With the above arrangement, the liquid adhering to the substrate can be removed without being scattered around while the rotational speed of the substrate is being slowly and gradually increased from a low rotational speed at a low rotational acceleration. Since the liquid adhering to the substrate can efficiently be removed, the maximum rotational speed of the substrate can be held to a low value. In addition, as the period of time for which the maximum rotational speed is kept is shortened, the time of the drying process is shortened.

According to a preferred aspect of the present invention, the substrate processing apparatus further comprises a drying unit for promoting the evaporation of a liquid adhering to the substrate held by the substrate holder, and a controller for controlling the drying unit.

The drying unit comprises a dry gas supply section, a heater, or a depressurizing unit, or the like, for example. The drying time of the substrate can further be shortened by promoting, with the drying unit, the evaporation of the liquid adhering to the substrate held by the substrate holder.

According to a preferred aspect of the present invention, the substrate processing apparatus further comprises a monitor for monitoring a humidity, a dew point, or a temperature in an atmosphere around the substrate held by the substrate holder, and sending a feedback signal to the controller.

With the above arrangement, the atmosphere such as humidity around the substrate held by the substrate holder is made more constant for keeping an environment to stably suppress water marks or the like.

Another substrate processing method according to the present invention comprises holding a substrate with a substrate holder, and rotating the substrate holder at a rotational speed which increases as a linear, quadratic, or higher-order function of a time that has elapsed from the start of drying the substrate at a rotational acceleration in the range from 0 to 300 rpm/s until the rotational speed of the substrate holder reaches a maximum rotational speed, thereby drying the substrate held by the substrate holder.

With the above method, by gradually increasing the rotational acceleration of the substrate and keeping the rotational acceleration of the substrate equal to or less than a predetermined value, the liquid adhering to the substrate can be removed without being scattered around, and the liquid removed from the substrate is prevented from splashing back to suppress the formation of water marks or the like.

It is preferable to keep the maximum rotational speed of the substrate equal to or less than 4000 rpm. By thus holding the maximum rotational speed of the substrate at a low level, the processing time of the substrate drying process can be shortened. Furthermore, the entrapment of air streams due to the rotation of the substrate can be reduced to suppress the formation of defects on the substrate.

At the time of the substrate drying process, the rotational speed of the substrate should preferably be kept at 500 rpm or lower. Thus, the liquid adhering to the substrate can be removed without being scattered around, and the liquid removed from the substrate is prevented from splashing back to suppress the formation of water marks or the like.

Still another substrate processing method according to the present invention comprises holding a substrate with a substrate holder, and rotating the substrate holder at a rotational speed which changes in n steps until the rotational speed of the substrate holder changes from an initial rotational speed at the start of drying the substrate to a maximum rotational speed, accelerating the substrate holder at a Katy rotational acceleration until the rotational speed thereof changes from a (k-1)th (2≦k≦n) rotational speed to a kth rotational speed, making the kth rotational speed greater than the (k-1)th rotational speed, and making the kth rotational acceleration greater than a (k-1)th rotational acceleration, thereby drying the substrate held by the substrate holder.

While the rotational speed of the substrate is being slowly and gradually increased from a low rotational speed at a low rotational acceleration, the liquid adhering to the substrate can be removed without being scattered around, and the liquid removed from the substrate is prevented from splashing back to suppress the formation of water marks or the like. As the liquid adhering to the substrate can be removed efficiently, the maximum rotational speed of the substrate is held to a low level. As the time to hold the maximum rotational speed can be shortened, the time of the drying process can be reduced.

It is preferable to set the first rotational speed of the substrate to 1000 rpm or less, and to set the first rotational acceleration to the range from 0 to 300 rpm (5 sec⁻²). Thus, liquid adhering to the substrate can be removed without being scattered around, and the liquid removed from the substrate is prevented from splashing back to suppress the formation of water marks or the like.

According to the present invention, since an atmosphere to which at least a portion of a surface of the substrate held by the substrate holder is exposed is turned into a humidity-controlled dry gas atmosphere, even if the surface of the substrate is hydrophobic or has fine patterns formed thereon, water droplets remaining on the substrate after a wet cleaning process can quickly be dried off by the humidity-controlled dry gas, preventing a defect referred to as water marks from being produced on the surface of the substrate and also preventing its device (forming) areas from being modified.

The substrate is rotated and dried while the amount of liquid droplets scattered around from the substrate holder and the substrate is small, and the rotational speed of the substrate is slowly and gradually increased from a low rotational speed at a low rotational acceleration, thereby preventing the liquid removed from the substrate from splashing back to suppress the formation of water marks or the like.

### BRIEF DESCRIPTION OF THE DRAWINGS

FIG. 1 is a diagram showing an example of a profile of substrate rotational speeds in a conventional substrate processing process;

FIG. 2 is a plan view of a substrate processing apparatus (system) according to an embodiment of the present invention;

FIG. 3 is a schematic view showing a polishing apparatus as a substrate processing apparatus according to an embodiment of the present invention, which is incorporated in the substrate processing apparatus shown in FIG. 2;

FIG. 4 is a schematic view showing an etching apparatus as a substrate processing apparatus according to an embodiment of the present invention, which is incorporated in the substrate processing apparatus shown in FIG. 2;

FIG. 5 is a schematic view showing a cleaning/drying apparatus as a substrate processing apparatus according to an embodiment of the present invention, which is incorporated in the substrate processing apparatus shown in FIG. 2;

FIG. 6 is a graph showing the relationship between the thickness of an oxide film (the thickness of a grown oxide film) and the left-to-stand time, the oxide film being grown when a dry gas controlled at 20° C. and a relative humidity of 58% was used and when a dry gas controlled at 20° C. and a relative humidity of 30% was used;

FIG. 7 is a schematic view showing a substrate processing apparatus according to another embodiment of the present invention;

FIG. 8 is a diagram showing the substrate rotational speed and rotational acceleration of the substrate processing apparatus shown in FIG. 7, and the mass of a liquid (liquid retrieval percentage) scattered from a substrate and a substrate holder and retrieved per unit time;

FIG. 9 is a schematic view showing a substrate processing apparatus according to still another embodiment of the present invention;

FIG. 10 is a diagram showing changes in the substrate rotational speed and rotational acceleration of the substrate processing apparatus shown in FIG. 9, and the humidity around a substrate;

FIG. 11 is a schematic view showing a substrate processing apparatus according to still another embodiment of the present invention;

FIG. 12 is a diagram showing changes in the substrate rotational speed and rotational acceleration of the substrate processing apparatus shown in FIG. 11, and the mist density around a substrate;

FIG. 13 is a schematic view showing a substrate processing apparatus according to still another embodiment of the present invention;

FIG. 14 is a diagram showing the substrate rotational speed and rotational acceleration of the substrate processing apparatus shown in FIG. 13, and the rate of reduction the area of a liquid-adhering portion of the surface of a substrate;

FIG. 15 is a schematic view showing a substrate processing apparatus according to still another embodiment of the present invention;

FIG. 16 is a diagram showing the substrate rotational speed and rotational acceleration of the substrate processing apparatus shown in FIG. 15, and the reduction rate of the mass of a substrate and a substrate holder;

FIG. 17 is a plan view of a plating apparatus incorporating a substrate processing apparatus according to an embodiment of the present invention;

FIG. 18 is a plan view of a plating apparatus incorporating a substrate processing apparatus according to an embodiment of the present invention;

FIG. 19 is a plan view of a cleaning apparatus incorporating a substrate processing apparatus according to an embodiment of the present invention;

FIG. 20 is a schematic view showing a substrate processing apparatus according to still another embodiment of the present invention;

FIG. 21 is a diagram showing an example of a profile of substrate rotational speeds in a substrate processing process;

FIG. 22 is a diagram showing another example of a profile of substrate rotational speeds in a substrate processing process;

FIG. 23 is a diagram showing still another example of a profile of substrate rotational speeds in a substrate processing process;

FIG. 24 is a diagram showing still another example of a profile of substrate rotational speeds in a substrate processing process;

FIG. 25 is a diagram showing still another example of a profile of substrate rotational speeds in a substrate processing process;

FIG. 26 is a diagram showing still another example of a profile of substrate rotational speeds in a substrate processing process;

FIG. 27 is a diagram showing still another example of a profile of substrate rotational speeds in a substrate processing process;

FIG. 28 is a diagram showing still another example of a profile of substrate rotational speeds in a substrate processing process;

FIG. 29 is a diagram showing still another example of a profile of substrate rotational speeds in a substrate processing process;

FIG. 30 is a diagram showing still another example of a profile of substrate rotational speeds in a substrate processing process;

FIG. 31 is a diagram showing still another example of a profile of substrate rotational speeds in a substrate processing process;

FIG. 32 is a diagram showing a measured increase in the number of defects on the surface of a substrate;

FIG. 33 is a diagram showing still another example of a profile of substrate rotational speeds in a substrate processing process;

FIG. 34 is a schematic view showing a substrate processing apparatus according to still another embodiment of the present invention;

FIG. 35 is a diagram showing still another example of a profile of substrate rotational speeds in a substrate processing process;

FIG. 36 is a graph showing the relationship between the rotational speed of a substrate wetted by a processing liquid when the substrate is rotated and the aerial mist count;

FIG. 37 is a graph showing the relationship between the liquid droplet diameter at the time a substrate wetted by a processing liquid is rotated at different maximum rotational speeds and the Weber number;

FIGS. 38A through 38C are diagrams schematically showing the relationship between the magnitude of the Weber number and the state of a liquid droplet;

FIG. 39 is a diagram showing the measured number of water marks on the surface of a substrate;

FIG. 40 is a plan view of a substrate processing apparatus (system) according to still another embodiment of the present invention;

FIGS. 41A through 41C are views showing a process of forming copper interconnects;

FIG. 42 is a plan view of a substrate processing apparatus (system) according to still another embodiment of the present invention; and

FIG. 43 is a plan view of a substrate processing apparatus (system) according to still another embodiment of the present invention.

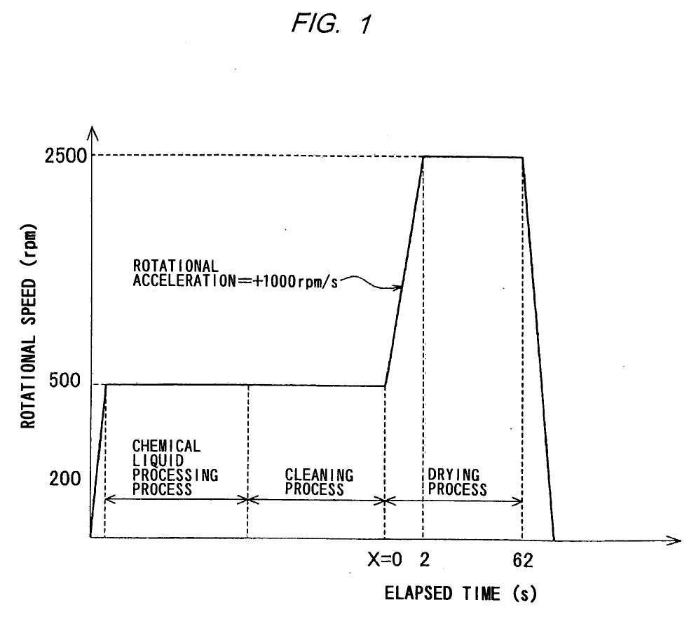

### DETAILED DESCRIPTION OF THE PREFERRED EMBODIMENTS

Embodiments of the present invention will hereinafter be described with reference to the drawings.

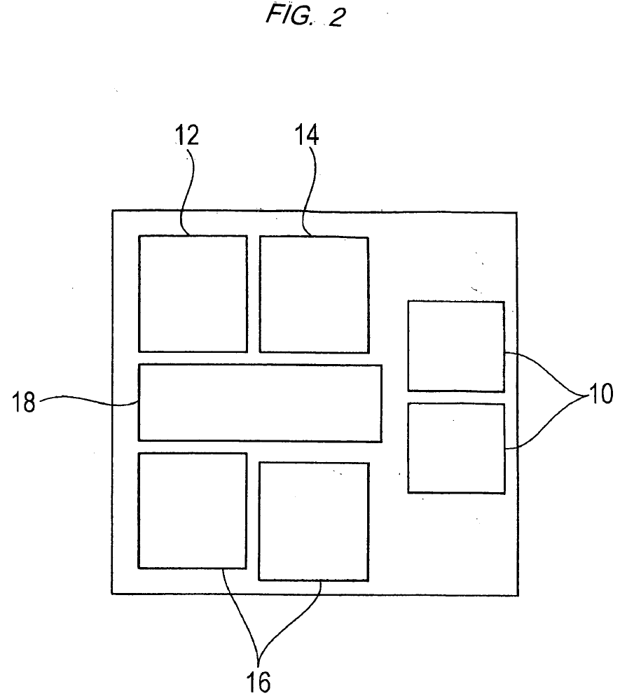

FIG. 2 is a view showing a planar layout of a substrate processing apparatus (system) according to an embodiment of the present invention. As shown in FIG. 2, the substrate processing system comprises two loading/unloading units 10 for placing thereon substrate cassettes housing substrates which each have a thin film deposited on its surface by, for example, sputtering, CVD, or plating, a polishing apparatus 12 for polishing away an unnecessary thin film deposited on or adhering to a bevel or edge portion of a substrate on which a thin film is formed, an etching apparatus 14 for etching away a thin film that remains on the bevel or edge portion of the substrate polished by the polishing apparatus 12, and cleaning/drying apparatuses 16 for cleaning and drying the substrate where the thin film on the bevel or edge portion thereof has been etched away by the etching apparatus 14. The substrate processing apparatus also comprises a transfer robot 18 for transferring substrates between the loading/unloading units 10, the polishing apparatus 12, the etching apparatus 14, and the cleaning/drying apparatuses 16.

In this embodiment, the cleaning/drying apparatus 16 clean and dry substrates. However, a cleaning apparatus for performing primary cleaning on a substrate and a cleaning/drying apparatus for performing secondary cleaning (finishing) on a substrate and drying on the substrate may separately be provided for performing primary cleaning and secondary cleaning (finishing) and drying separately.

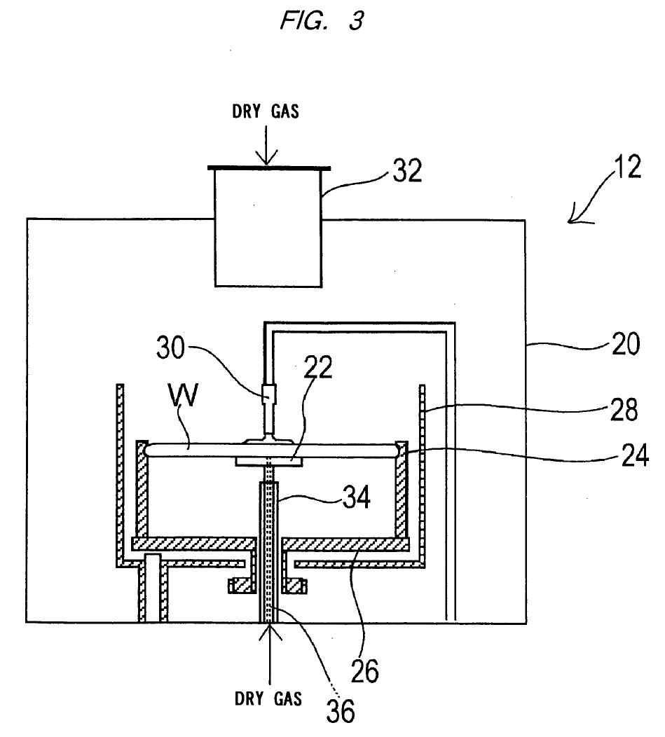

FIG. 3 schematically shows a polishing apparatus 12 as a substrate processing apparatus according to an embodiment of the present invention, which is incorporated in the substrate processing apparatus (system) shown in FIG. 2. As shown in FIG. 3, the polishing apparatus (substrate processing apparatus) 12 has a rotatable substrate holder 22 disposed in a processing chamber 20 for detachably holding the reverse side of a substrate W with its surface (to be processed) facing upwardly, a rotatable rotor 26 supporting a polishing tool 24 in the form of a grinding stone, a polishing pad, or the like, for example, for movement toward and away from a bevel or edge portion of the substrate W held by the substrate holder 22, and a cylindrical scattering prevention cover 28 surrounding the polishing tool 24 and the rotor 26 for preventing a liquid supplied to the surface of the substrate W from being scattered around. A liquid supply nozzle 30 for supplying a liquid such as a polishing solution, pure water, or the like, for example, to the upper surface of the substrate W is positioned above the substrate W that is held by the substrate holder 22.

To the processing chamber 20, there is connected a first dry gas supply pipe 32, which serves as a first dry gas supply section, for introducing a humidity-controlled dry gas such as an inactive gas, e.g., an Ar gas, an N₂ gas, or the like, or clean air or the like into the processing chamber 20. A vertically extending support rod 34 which has an upper end joined to the substrate holder 22 houses therein a second dry gas supply pipe 36, which serves as a second dry gas supply section, for passing a humidity-controlled dry gas such as an inactive gas, e.g., an Ar gas, an N₂ gas, or the like, or clean air or the like therethrough and introducing the dry gas between the substrate holder 22 and the substrate held by the substrate holder 22.

In this embodiment, while the polishing tool 24 is being rotated by the rotor 26, the polishing tool 24 is pressed against the bevel or edge portion of the substrate W that is held by the substrate holder 22, and at the same time a polishing solution such as a slurry, for example, is supplied from the liquid supply nozzle 30 to the upper surface of the substrate W, thereby polishing the bevel or edge portion of the substrate W with the polishing tool 24. After the polishing of the substrate W is finished, the polishing tool 24 is spaced from the bevel or edge portion of the substrate W, and the substrate holder 22 is rotated. At the same time, a cleaning liquid (rinsing liquid) such as pure water or the like is supplied from the liquid supply nozzle 30 to the surface of the substrate W to clean (rinse) the substrate W. Thereafter, the supply of the cleaning liquid is stopped, and the substrate W is rotated at a high speed so as to be spin-dried.

During the cleaning and spin-drying process, a humidity-controlled dry gas such as an inactive gas, e.g., an Ar gas, an N₂ gas, or the like, or clean air or the like is introduced from the first dry gas supply pipe (first dry gas supply section) 32 into the processing chamber 20, and simultaneously a humidity-controlled dry gas such as an inactive gas, e.g., an Ar gas, an N₂ gas, or the like, or clean air or the like is introduced from the second dry gas supply pipe (second dry gas supply section) 36 between the substrate holder 22 and the substrate W held by the substrate holder 22. Since the atmosphere to which at least a portion of the surface of the substrate W held by the substrate holder 22 is exposed is a dry gas atmosphere whose humidity is controlled, even if the surface of the substrate W held by the substrate holder 22 is hydrophobic or has fine patterns formed thereon, water droplets remaining on the substrate W after the wet cleaning process can quickly be dried off by the humidity-controlled dry gas, whereby preventing a defect referred to as water marks from being produced on the surface of the substrate W and also preventing its device (to be formed) areas from being modified.

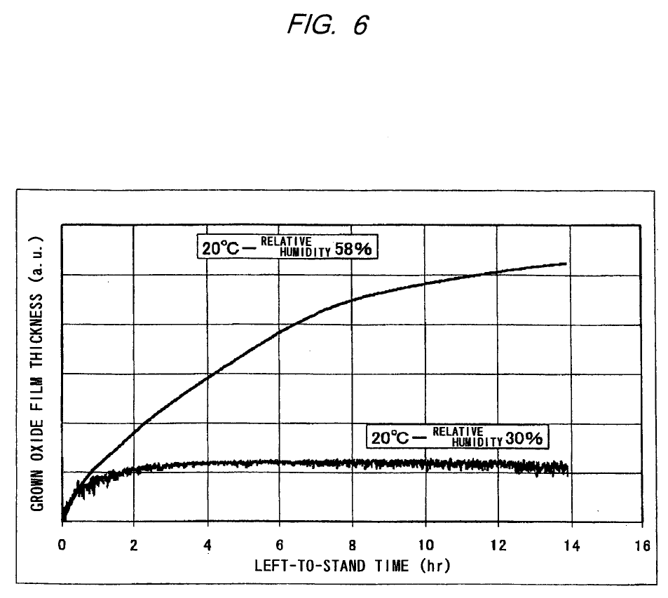

The dry gas comprises a gas having a humidity not more than an ordinary relative humidity (not more than about 40%) at an ordinary temperature (20° C.) in a clean room where the substrate is processed. Preferably, the dry gas comprises an inactive gas, e.g., an Ar gas, an N₂ gas, or the like, for example, whose relative humidity is controlled in the range from 0 to 30%, for efficiently drying the substrate to effectively suppress the formation of water marks. FIG. 6 is a graph showing the relationship between the thickness of an oxide film (the thickness of a grown oxide film) and the left-to-stand time, the oxide film being grown when a dry gas controlled at 20° C. and a relative humidity of 58% was used and when a dry gas controlled at 20° C. and a relative humidity of 30% was used. It can be seen from the graph that the growth of an oxide gas can effectively be suppressed by using a dry gas controlled at 20° C. and a relative humidity of 30%.

An inactive gas, e.g., an Ar gas, an N₂ gas, or the like is generally expensive. If a substrate made of a material of low reactivity, for example, is used, then inexpensive atmospheric air (clean air) whose relative humidity is controlled in the range from 0 to 30% may be used as the dry gas for efficiently drying the substrate to suppress the formation of water marks.

Inasmuch as the atmosphere to which at least a portion of the surface of the substrate W held by the substrate holder 22 is exposed needs to be filled with a dry gas, the volume of the dry gas supplied from the dry gas supply sections 32, 36 may be equal to or greater than the total volume of air that is discharged from the processing chamber 20 when the dry gas is supplied. Preferably, the volume of the dry gas may be 0.5 to 3 times the total volume of discharged air. Thus, a sufficient volume of dry gas large enough to dry the substrate W can be obtained.

The above relative humidity and volume of the dry gas hold true for each of the examples to be described below.

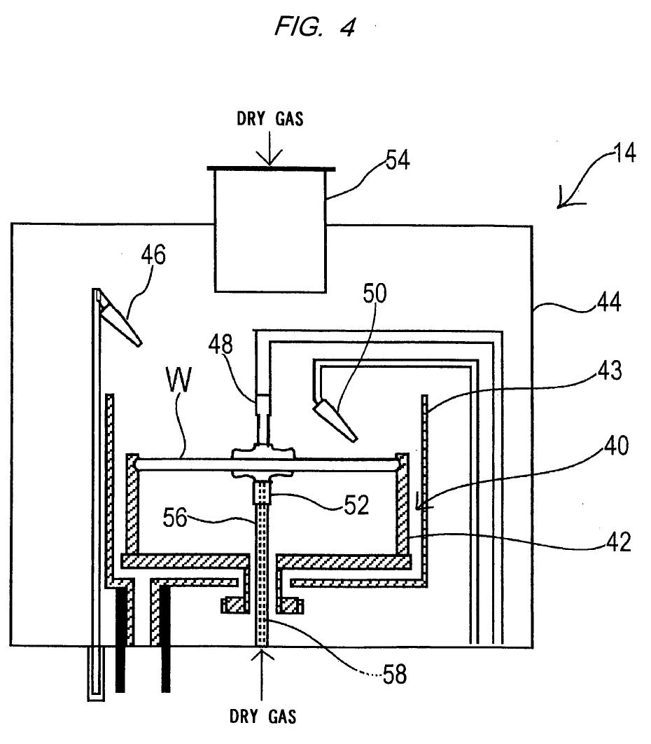

FIG. 4 schematically shows an etching apparatus 14 as a substrate processing apparatus according to an embodiment of the present invention, which is incorporated in the substrate processing apparatus (system) shown in FIG. 2. The etching apparatus (substrate processing apparatus) 14 has a substrate holder 40 for holding the substrate W with its surface (to be processed) facing upwardly and rotating the substrate W. The substrate holder 40 has a plurality of rotation supports 42 disposed outwardly of the substrate W and movable inwardly. The rotation supports 42 are moved inwardly to grip and hold the substrate W laterally, and then are rotated to rotate the substrate W. The substrate holder 40 is surrounded by a scattering prevention cover 43 disposed in a processing chamber 44.

A cleaning liquid supply nozzle 46 for supplying a cleaning liquid such as pure water or the like to a substantially central area of the surface of the substrate W held by the substrate holder 40 is positioned laterally of the substrate holder 40. A first liquid supply nozzle 48 for supplying a liquid such as a chemical liquid (etching liquid) or the like to the central area of the surface of the substrate W, and a second liquid supply nozzle 50 for supplying a liquid such as a chemical liquid (etching liquid) or the like to a bevel or edge portion of the substrate W are positioned above the substrate W that is held by the substrate holder 40. A third liquid supply nozzle 52 for supplying a liquid such as pure water, a chemical liquid (etching liquid), or the like to a substantially central area of the reverse side of the substrate W held by the substrate holder 40 is vertically positioned at the substantially central area of the reverse side of the substrate W held by the substrate holder 40.

As with the above-described polishing apparatus 12, to the processing chamber 44, there is connected a first dry gas supply pipe 54, which serves as a first dry gas supply section, for introducing a humidity-controlled dry gas such as an inactive gas, e.g., an Ar gas, an N₂ gas, or the like, or clean air or the like into the processing chamber 44. A vertically extending liquid supply pipe 56, which has an upper end joined to the third liquid supply nozzle 52, houses therein a second dry gas supply pipe 58, which serves as a second dry gas supply section, for passing a humidity-controlled dry gas such as an inactive gas, e.g., an Ar gas, an N₂ gas, or the like, or clean air or the like therethrough and spraying the dry gas onto the reverse side of the substrate W held by the substrate holder 40.

In this embodiment, a chemical liquid (first etching liquid) is supplied from the first liquid supply nozzle 48 to the surface of the substrate W which is held and rotated by the substrate holder 40, and spread over the entire surface of the substrate W under centrifugal forces on the substrate W. At the same time, a chemical liquid (second etching liquid) is supplied from the second liquid supply nozzle 50 to the bevel or edge portion of the substrate W for thereby etching the bevel or edge portion of the substrate W. Simultaneously, if necessary, pure water or a chemical liquid (etching liquid) is supplied from the third liquid supply nozzle 52 to the reverse side of the substrate W, cleaning the reverse side of the substrate W with the pure water or etching the reverse side of the substrate W with the etching liquid. After this process is finished, a chemical liquid (etching liquid) is supplied from the cleaning liquid supply nozzle 46 to the surface of the substrate while the substrate W is being rotated. Furthermore, if necessary, a cleaning liquid (rinsing liquid) such as pure water or the like is supplied from the third liquid supply nozzle 52 to the reverse side of the substrate W, simultaneously cleaning (rinsing) the surface and reverse side of the substrate W. Thereafter, the supply of the cleaning liquid is stopped, and the substrate W is spin-dried.

During the cleaning and spin-drying process, substantially in the same manner as described above, a humidity-controlled dry gas such as an inactive gas, e.g., an Ar gas, an N₂ gas, or the like, or clean air or the like is introduced from the first dry gas supply pipe (first dry gas supply section) 54 into the processing chamber 44, and simultaneously a humidity-controlled dry gas such as an inactive gas, e.g., an Ar gas, an N₂ gas, or the like, or clean air or the like is sprayed from the second dry gas supply pipe (second dry gas supply section) 58 onto the reverse side of the substrate W held by the substrate holder 40. In this fashion, water droplets that remain on the substrate W after the wet cleaning process can quickly be dried off by the humidity-controlled dry gas.

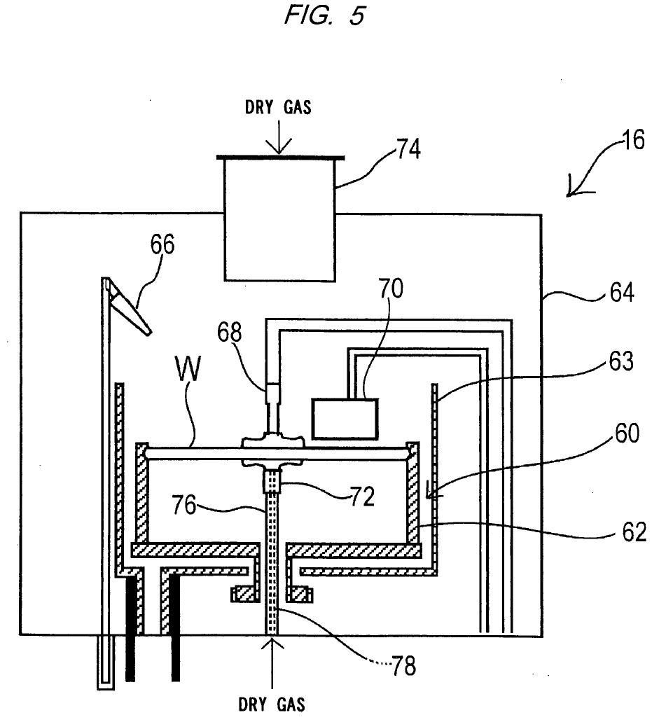

FIG. 5 schematically shows a cleaning/drying apparatus 16 as a substrate processing apparatus according to an embodiment of the present invention, which is incorporated in the substrate processing apparatus (system) shown in FIG. 2. The cleaning/drying apparatus (substrate processing apparatus) 16 has a substrate holder 60 for holding the substrate W with its surface (to be processed) facing upwardly and rotating the substrate W. The substrate holder 60 has a plurality of rotation supports 62 disposed outwardly of the substrate W and movable inwardly. The rotation supports 62 are moved inwardly to grip and hold the substrate W laterally, and then are rotated to rotate the substrate W. The substrate holder 60 is surrounded by a scattering prevention cover 63 disposed in a processing chamber 64.

A cleaning liquid supply nozzle 66 for supplying a cleaning liquid such as pure water or the like to a substantially central area of the surface of the substrate W held by the substrate holder 60 is positioned laterally of the substrate holder 60. A first liquid supply nozzle 68 for supplying a liquid such as a chemical liquid (cleaning liquid) or the like to the central area of the surface of the substrate W is positioned above the substantially central area of the substrate W held by the substrate holder 60. A cleaning member 70 made of e.g., polyvinyl alcohol (PVA) or a non-woven fabric for rubbing against the upper surface of the substrate W held by the substrate holder 60 to scrub the surface of the substrate W is vertically movably positioned laterally of the first liquid supply nozzle 68. A second liquid supply nozzle 72 for supplying a liquid such as a chemical liquid (cleaning liquid) or the like to a substantially central area of the reverse side of the substrate W held by the substrate holder 60 is positioned at a substantially central area of the reverse side of the substrate W held by the substrate holder 60.

As with the above-described etching apparatus 14, to the processing chamber 64, there is connected a first dry gas supply pipe 74, which serves as a first dry gas supply section, for introducing a humidity-controlled dry gas such as an inactive gas, e.g., an Ar gas, an N₂ gas, or the like, or clean air or the like into the processing chamber 64. A vertically extending liquid supply pipe 76, which has an upper end joined to the second liquid supply nozzle 72, houses therein a second dry gas supply pipe 78, which serves as a second dry gas supply section, for passing a humidity-controlled dry gas such as an inactive gas, e.g., an Ar gas, an N₂ gas, or the like, or clean air or the like therethrough and spraying the dry gas onto the reverse side of the substrate W held by the substrate holder 60.

In this embodiment, a chemical liquid (cleaning liquid) is supplied from the first liquid supply nozzle 68 to the surface of the substrate W which is held and rotated by the substrate holder 60, and at the same time the cleaning member 70 rubs against the surface of the substrate W to clean (scrub) the surface of the substrate W. At the same time, if necessary, a chemical liquid (cleaning liquid) is supplied from the second liquid supply nozzle 72 to the reverse side of the substrate W for thereby cleaning the reverse side of the substrate W with the chemical liquid (cleaning liquid). After this process is finished, the cleaning member 70 is spaced from the substrate W. While the substrate W is being rotated, the cleaning liquid (rinsing liquid) is supplied from the cleaning liquid supply nozzle 66 to the surface of the substrate W, and, if necessary, the cleaning liquid (rinsing liquid) such as pure water or the like is supplied from the second liquid supply nozzle 72 to the reverse side of the substrate W, cleaning (rinsing) the surface and reverse side of the substrate W. Thereafter, the supply of the cleaning liquid is stopped, and the substrate W is spin-dried.

During the cleaning and spin-drying process, substantially in the same manner as described above, a humidity-controlled dry gas such as an inactive gas, e.g., an Ar gas, an N₂ gas, or the like, or clean air or the like is introduced from the first dry gas supply pipe (first dry gas supply section) 74 into the processing chamber 64, and simultaneously a humidity-controlled dry gas such as an inactive gas, e.g., an Ar gas, an N₂ gas, or the like, or clean air or the like is sprayed from the second dry gas supply pipe (second dry gas supply section) 78 onto the reverse side of the substrate W held by the substrate holder 60. In this fashion, water droplets that remain on the substrate W after the wet cleaning process can quickly be dried off by the humidity-controlled dry gas.

Processing of the substrate in the substrate processing apparatus (system) shown in FIG. 2 will be described below.

First, a substrate W having a thin film deposited on its surface by sputtering, CVD, or plating is taken by the transfer robot 18 out of the substrate cassette placed on one of the loading/unloading units 10, and transferred to the polishing apparatus 12. In the polishing apparatus 12, the unnecessary thin film deposited on or adhering to a bevel or edge portion of the substrate W is polished away. At this time, the thin film deposited on or adhering to the bevel or edge portion of the substrate W is not entirely removed, but is slightly left thereon. The substrate W which has been polished by the polishing apparatus 12 is cleaned with a cleaning liquid (rinsing liquid) such as pure water or the like and then spin-dried. Thereafter, the substrate W is transferred to the etching apparatus 14. Next, in the etching apparatus 14, the thin film deposited on or adhering to the bevel or edge portion of the substrate W is etched away, and then the substrate is cleaned with a cleaning liquid (rinsing liquid) such as pure water or the like and then spin-dried.

Since the thin film deposited on or adhering to the bevel or edge portion of the substrate W is polished away by the polishing apparatus 12, even if the thin film comprises a hard film such as a silicon nitride film (Si₂N₄) or a tantalum oxide film (Ta₂O₅), it can be removed within a short period of time while providing a steep edge profile. Thereafter, the thin film remaining on the bevel or edge portion is completely etched away by the etching apparatus 14, so that any surface roughness of the bevel or edge portion is held to a small level.

The substrate W whose bevel or edge portion has been etched by the etching apparatus 14 is then transferred to the cleaning/drying apparatus 16. The substrate W is cleaned and spin-dried by the cleaning/drying apparatus 16, the spin-dried substrate W is then returned to the substrate cassette placed on the loading/unloading unit 10.

In the above embodiment, the polishing apparatus has a polishing tool in the form of a grinding stone or a polishing pad, and polishes the substrate while supplying a polishing solution such as a slurry or the like. However, the polishing apparatus may employ any of other polishing processes, such as an electrolytic polishing process, an electric discharge polishing process, or an ultrasonic polishing process, and may employ a polishing tool made of an abrasive material or a material coated with an abrasive material. Furthermore, while polishing the substrate, the polishing apparatus may supply pure water, electrolyzed water, or gas-dissolved water to the substrate.

In the etching apparatus (substrate processing apparatus) 14, the substrate W, which is held and rotated by the substrate holder 40, is supplied with a chemical liquid (etching liquid) from the first liquid supply nozzle 48 and the second liquid supply nozzle 50 to etch the bevel or edge portion of the substrate W. At the same time, a humidity-controlled dry gas may be introduced from the first dry gas supply pipe (first dry gas supply section) 54 into the processing chamber 44. Furthermore, if necessary, a humidity-controlled dry gas may be sprayed from the second dry gas supply pipe (second dry gas supply section) 58 onto the reverse side of the substrate W held by the substrate holder 40.

When the chemical liquid is supplied to the substrate W to etch the substrate W in the etching apparatus 14, the chemical liquid impinges upon the substrate W, the substrate holder 40, and the inner walls of the scattering prevention cover 43, and the like, producing minute liquid droplets. If those minute liquid droplets adhere again to the substrate W, the substrate W is oxidized and etched at the spots where the minute liquid droplets adhere. Particularly, when the bevel portion is etched, because the portion of the substrate W other than the bevel portion thereof needs to be prevented from being etched, the adherence of minute chemical liquid droplets to the substrate W poses a problem. When the substrate W is rotated, an air stream tends to be generated which rises near and along the inner wall of the apparatus and then falls toward the center of the substrate W, the minute liquid droplets move on the air stream and tend to adhere to the substrate W near its central area.

In this embodiment, a humidity-controlled dry gas is introduced from the first dry gas supply pipe (first dry gas supply section) 54 into the processing chamber 44. Since the substrate W is etched while the processing chamber 44 is being filled with the dry gas atmosphere, those minute liquid droplets are evaporated and hence prevented from adhering again. The portion to be protected of the substrate W is thus prevented from being damaged (oxidized and etched), and only the film is removed from the portion of the substrate W that is to be etched.

This also holds true for the polishing apparatus (substrate processing apparatus) 12, and the substrate W may be polished while the processing chamber is being supplied with a dry gas. Furthermore, also in the cleaning/drying apparatus (substrate processing apparatus) 14, the substrate W may be dried only while the processing chamber is being supplied with a dry gas.

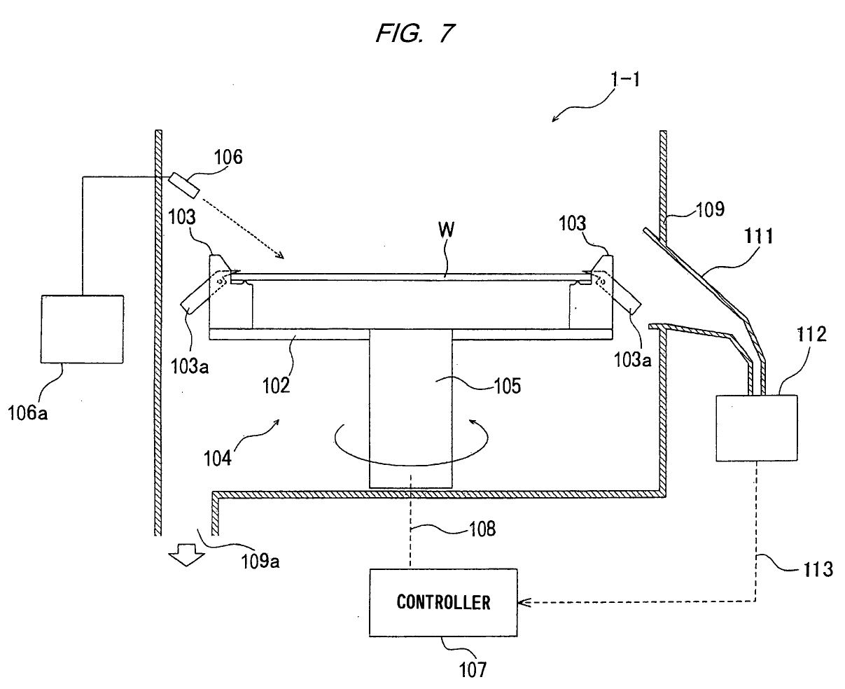

FIG. 7 shows a general structure of a substrate processing apparatus according to still another embodiment of the present invention. A substrate processing apparatus 1-1 shown in FIG. 7 has a rotational shaft 105 and a substrate holder 104. The substrate holder 104 has a plurality of bases 102 extending radially outwardly horizontally from the upper end of the rotational shaft 105, and substrate holding mechanisms 103 mounted on the distal ends of the bases 102. The bases 102 and the substrate holding mechanisms 103 are provided in a plurality of sets (three or more sets). A substrate W such as a semiconductor wafer or the like to be processed is placed centrally on the substrate holding mechanisms 103, and gripped by substrate pressers 103a of the substrate holding mechanisms 103. The substrate pressers 103a are rotatably supported by pivot pins at their portions above their centers of gravity, and are normally disposed parallel to the rotational shaft 105 by gravity. When the rotational shaft 105 rotates, the portions of the substrate pressers 103a below the pivot pins are moved outwardly and lifted under centrifugal forces acting on the substrate pressers 103a, and the portions of the substrate pressers 103a above the pivot pins are lowered inwardly to press the substrate W, thereby gripping the substrate W. The rotational shaft 105 is coupled to an actuator (not shown). With the substrate W held by the substrate holding mechanisms 103, the substrate holder 104 is rotated about the rotational shaft 105. The substrate holder 104 is connected to a controller 107 by a control signal line 108, and the controller 107 accelerates/decelerates the substrate holder 104 at a desired acceleration and rotates the substrate holder 104 at a target rotational speed according to a control signal from the controller 107.

A processing liquid supply nozzle 106 for supplying a processing liquid such as a chemical liquid, a cleaning liquid, or the like to the surface of the substrate W is disposed above the substrate holder 104. The rate of the processing fluid supplied from the processing liquid supply nozzle 106 or the like is regulated by a processing fluid supply system 106a that is connected to the processing liquid supply nozzle 106.

A scattering prevention cup 109 for preventing the processing liquid supplied to the substrate W from being scattered around is disposed around the side of the substrate holder 104. The scattering prevention cup 109 receives the processing liquid scattered from the substrate holding mechanisms 103 and the substrate W, and discharges the processing liquid from a waste liquid drain port 109a defined in a lower portion thereof. The cleaning liquid used to rinse the substrate W generally comprises DIW (pure water) or gas-dissolved water. Depending on the purpose, the substrate W may be cleaned using another chemical liquid.

The substrate processing apparatus 1-1 has a liquid droplet collector 112, disposed on the sidewall of the scattering prevention cup 109 at a position facing the substrate holding mechanisms 103, for collecting liquid droplets of the processing liquid that is scattered from the substrate holding mechanisms 103 and the substrate W. The liquid droplets collected by the liquid droplet collector 112 are guided to a high-precision mass meter (monitor) 112, which measures the mass of the liquid droplets. The mass meter 112 and the controller 107 are connected to each other by a control signal line 113, so that the mass of the liquid droplets, which is measured by the mass meter 112, is sent by way of feedback to the controller 107. The substrate processing apparatus 1-1 can successively perform a substrate processing process using a chemical liquid, a substrate cleaning process, and a substrate drying process. In each of these processes, the rotational speed and rotational acceleration of the substrate W are controlled by the controller 107.

The procedure of the substrate processing process using a chemical liquid, the substrate cleaning process, and the substrate drying process, which is performed by the substrate processing apparatus 1-1, will simply be described below. First, the substrate W to be processed is placed centrally on the substrate holding mechanisms 103 by a robot hand or the like (not shown), and then gripped by the substrate holders 103a. Thereafter, the substrate holder 104 is rotated to rotate the substrate W. Then, a chemical liquid is supplied from the processing liquid supply nozzle 106 to the substrate W to process the substrate W with the chemical liquid (the chemical liquid processing process). Then, while the substrate W is being rotated, a cleaning liquid such as DIW or the like is supplied from the processing liquid supply nozzle 106 to the substrate W to clean (rinse) the substrate W (the substrate cleaning process). When the substrate cleaning process is finished, the substrate W is rotated at a high speed to expel and remove the liquid, such as the cleaning liquid or the like, adhering to the substrate W, thus drying the substrate W (the substrate drying process).

In the substrate drying process, liquid droplets expelled and scattered around from the substrate holding mechanisms 103 and the substrate W are collected by the liquid droplet collector 111, and the mass of the collected liquid droplets is measured by the mass meter 112. The mass of the liquid droplets which is measured by the mass meter 112 is sent by way of feedback to the controller 107, which controls the rotational speed of the substrate holder 104 such that the retrieval percentage of liquid droplets scattered around from the substrate holding mechanisms 103 and the substrate W will be kept equal to or smaller than a constant value. Thus, since the substrate W can be rotated and dried while the amount of liquid droplets scattered around from the substrate holding mechanisms 103 and the substrate W is small, the liquid removed from the substrate W is prevented from splashing back to suppress the formation of water marks or the like.

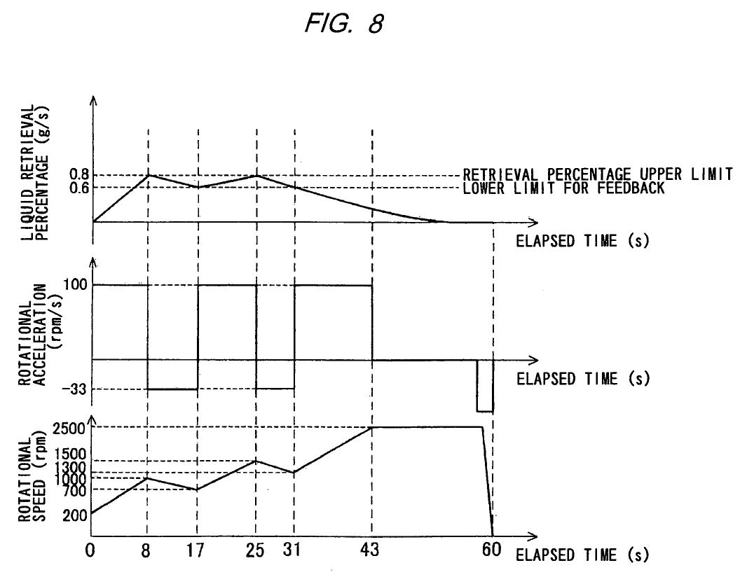

FIG. 8 is a diagram showing the rotational speed (rpm) and rotational acceleration (rpm/s) of the substrate W with respect to the time (s) that has elapsed from the start of the substrate drying process, and the mass of the liquid (liquid retrieval percentage) (g/s) scattered from the substrate W and the substrate holder 104 and retrieved per unit time, during the substrate drying process performed using the substrate processing apparatus 1-1. The rotational speed of the substrate W is increased for a certain period of time, then reduced, and increased again for a certain period of time. This sequence is repeated to gradually increase the rotational speed, after which the substrate rotational speed is kept at a maximum level for a certain period of time. By thus controlling the rotational speed of the substrate W, the retrieval percentage of the liquid retrieved per unit time is kept equal to or smaller than a predetermined upper limit until the retrieval percentage becomes nil.

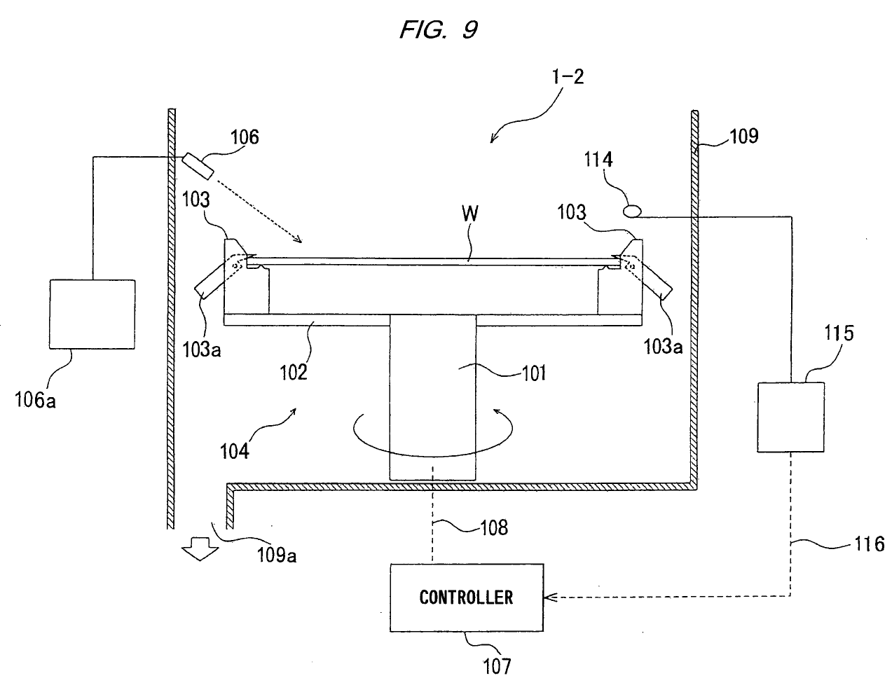

FIG. 9 shows a general structure of a substrate processing apparatus according to still another embodiment of the present invention. Those parts of the substrate processing apparatus 1-2 shown in FIG. 9 which are common to those of the substrate processing apparatus 1-1 shown in FIG. 7 are denoted by identical reference characters, and will not be described in detail below. This also holds true for substrate processing apparatus according to other embodiments to be described later.

The substrate processing apparatus 1-2 shown in FIG. 9 differs from the substrate processing apparatus 1-1 shown in FIG. 7 in that the liquid droplet collector 111 and the mass meter 112 shown in FIG. 7 are replaced with a hygrometer (monitor) 115 having a sensor 114 for measuring the humidity around the substrate holding mechanisms 103 and the substrate W that are disposed in the scattering prevention cup 109. The hygrometer 115 and the controller 107 are connected to each other by a control signal line 116, so that the humidity around the substrate W which is measured by the hygrometer 115 is sent by way of feedback to the controller 107.

The substrate processing apparatus 1-2 can successively perform a substrate processing process using a chemical liquid, a substrate cleaning process, and a substrate drying process in the same manner as the substrate processing apparatus 1-1 shown in FIG. 7. Therefore, these processes will not be described below. This also holds true for substrate processing apparatus according to other embodiments to be described later.

With the substrate processing apparatus 1-2, in the substrate drying process, liquid droplets expelled and scattered around from the substrate holding mechanisms 103 and the substrate W impinge upon the scattering prevention cup 109, etc. and are turned into a mist, so that the humidity around the substrate W is changed. The sensor 114 of the hygrometer 115 measures the humidity around the substrate holding mechanisms 103 and the substrate W. The humidity around the substrate W which is measured by the sensor 114 of the hygrometer 115 is sent by way of feedback to the controller 107, which controls the rotational speed of the substrate holder 104 such that the measured humidity or a rate of increase thereof will be kept equal to or smaller than a certain constant value. Thus, the rotational speed of the substrate holder 104 can be controlled to keep the amount of liquid droplets scattered around from the substrate holding mechanisms 103 and the substrate W below a certain level by sending the humidity measured by the hygrometer 115 by way of feedback to the controller 107. Therefore, as the substrate W can be rotated and dried while the amount of liquid droplets scattered around from the substrate holding mechanisms 103 and the substrate W is small in the substrate drying process, the liquid removed from the substrate W is prevented from splashing back to suppress the formation of water marks or the like.

FIG. 10 is a diagram showing the rotational speed (rpm) and rotational acceleration (rpm/s) of the substrate W with respect to the time (s) that has elapsed from the start of the substrate drying process, and the humidity (%) around the substrate W, during the substrate drying process performed using the substrate processing apparatus 1-2. The rotational speed of the substrate W is increased for a certain period of time, then reduced, and increased again for a certain period of time. This sequence is repeated to gradually increase the rotational speed, after which the substrate rotational speed is kept at a maximum level for a certain period of time. By thus controlling the rotational speed of the substrate W, the humidity is kept equal to or smaller than a predetermined upper limit until the humidity around the substrate W reaches a level at the start of the substrate drying process.

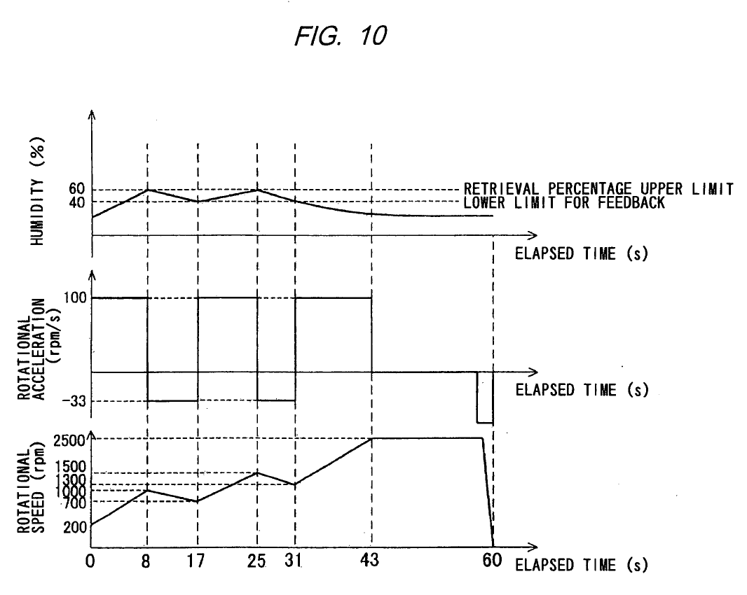

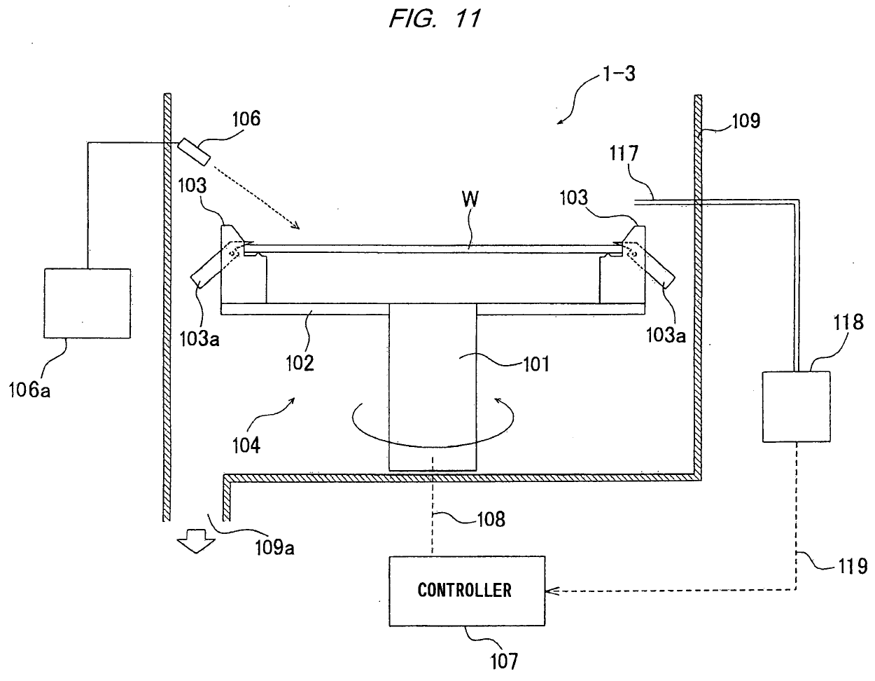

FIG. 11 shows a general structure of a substrate processing apparatus according to still another embodiment of the present invention. The substrate processing apparatus 1-3 shown in FIG. 11 differs from the substrate processing apparatus 1-1 shown in FIG. 7 in that the liquid droplet collector 111 and the mass meter 112 shown in FIG. 7 are replaced with a mist suction section 117 that is open into the scattering prevention cup 109, and a mist measuring instrument (monitor) 118 connected to the mist suction section 117. The mist measuring instrument 118 and the controller 107 are connected to each other by a control signal line 119, so that the amount of the mist which is measured by the mist measuring instrument 108 is sent by way of feedback to the controller 107.

With the substrate processing apparatus 1-3, in the substrate drying process, liquid droplets expelled and scattered around from the substrate holding mechanisms 103 and the substrate W impinge upon the scattering prevention cup 109 and are turned into a mist. The mist around the substrate W is drawn from the mist suction section 117 into the mist measuring instrument 118, which measures the amount of the mist around the substrate W. The amount of the mist around the substrate W which is measured by the mist measuring instrument 118 is sent by way of feedback to the controller 107, which controls the rotational speed of the substrate holder 104 such that the measured humidity or a rate of increase thereof will be kept equal to or smaller than a certain constant value. Thus, the rotational speed of the substrate holder 104 can be controlled to keep the amount of liquid droplets scattered around from the substrate holding mechanisms 103 and the substrate W below a certain level by sending the humidity measured by the mist measuring instrument 118 by way of feedback to the controller 107. Therefore, as the substrate W can be rotated and dried while the amount of liquid droplets scattered around from the substrate holding mechanisms 103 and the substrate W is small in the substrate drying process, the liquid removed from the substrate W is prevented from splashing back to suppress the formation of water marks or the like.

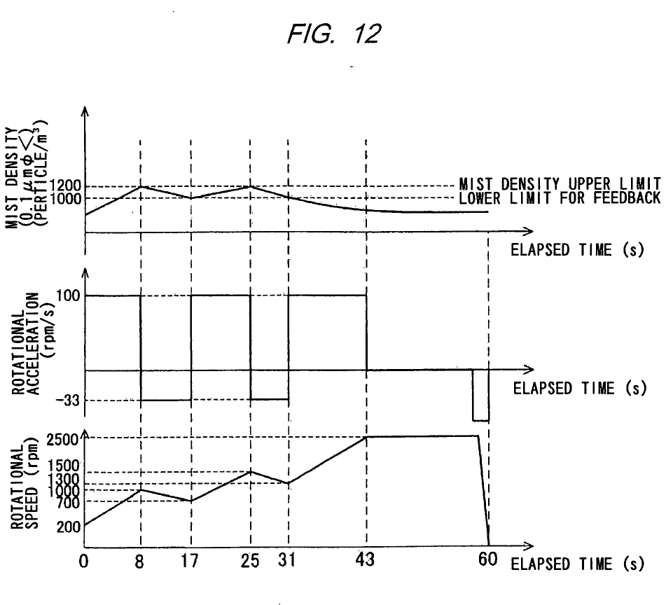

FIG. 12 is a diagram showing the rotational speed (rpm) and rotational acceleration (rpm/s) of the substrate W with respect to the time (s) that has elapsed from the start of the substrate drying process, and a change of the mist density (0.1 μm diameter<) around the substrate W, during the substrate drying process performed using the substrate processing apparatus 1-3. The rotational speed of the substrate W is increased for a certain period of time, then reduced, and increased again for a certain period of time. This sequence is repeated to gradually increase the rotational speed, after which the substrate rotational speed is kept at a maximum level for a certain period of time. By thus controlling the rotational speed of the substrate W, the mist density is kept equal to or smaller than a predetermined upper limit until the mist density around the substrate W reaches a level at the start of the substrate drying process.

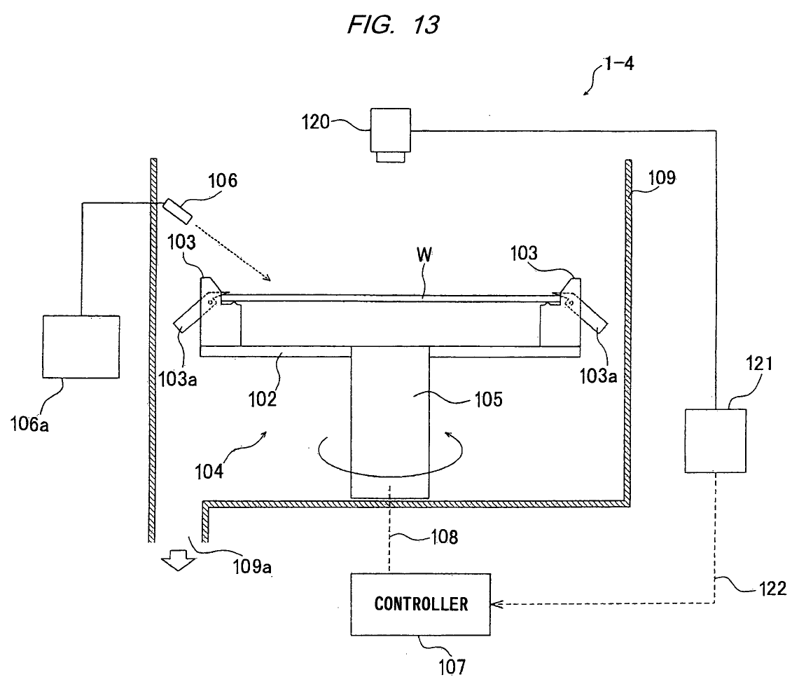

FIG. 13 shows a general structure of a substrate processing apparatus according to still another embodiment of the present invention. The substrate processing apparatus 1-4 shown in FIG. 13 differs from the substrate processing apparatus 1-1 shown in FIG. 7 in that the liquid droplet collector 111 and the mass meter 112 shown in FIG. 7 are replaced with an image capturing camera 120 for capturing an image of the surface of the substrate W, and an image processor 121 connected to the image capturing camera 120, which make up a liquid droplet adhering area measuring mechanism (monitor). The image processor 121 is arranged to analyze the image of the surface of the substrate W which is captured by the image capturing camera 120 and measures the area of a portion of the surface of the substrate W to which the liquid adheres. The image processor 121 and the controller 107 are connected to each other by a control signal line 122, so that the area, measured by the image processor 121, of the portion of the surface of the substrate W to which the liquid adheres is sent by way of feedback to the controller 107.

A CCD camera, an infrared camera or a laser-focus displacement gage, for example, may be used as the image capturing camera 120.

With the substrate processing apparatus 1-4, in the substrate drying process, the substrate processing liquid supplied in the preceding substrate cleaning process adheres to the surface of the substrate W. The image capturing camera 120 captures an image of the surface of the substrate W, and transmits the image to the image processor 121, which analyzes the captured image to measure the area of the portion of the surface of the substrate W to which the liquid adheres. The area, measured by the image processor 121, of the portion of the surface of the substrate W to which the liquid adheres is sent by way of feedback to the controller 107, which controls the rotational speed of the substrate holder 104 such that the measured area of the portion of the surface of the substrate W to which the liquid adheres, or a rate of reduction thereof is kept below a certain level. By thus sending the area, measured by the image processor 121, of the portion of the surface of the substrate W to which the liquid adheres by way of feedback to the controller 107, the rotational speed of the substrate W can be controlled such that the amount of liquid droplets scattered around from the substrate holding mechanisms 103 and the substrate W is kept below a certain level. Therefore, as the substrate W can be rotated and dried while the amount of liquid droplets scattered around from the substrate holding mechanisms 103 and the substrate W is small in the substrate drying process, the liquid removed from the substrate W is prevented from splashing back to suppress the formation of water marks or the like.

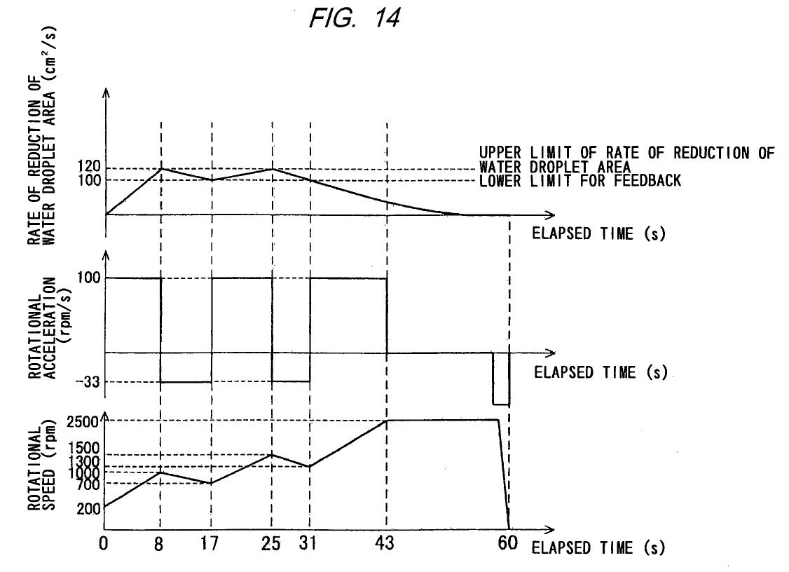

FIG. 14 is a diagram showing the rotational speed (rpm) and rotational acceleration (rpm/s) of the substrate W with respect to the time (s) that has elapsed from the start of the substrate drying process, and the rate of reduction (cm²/s) of the area of the portion of the surface of the substrate W to which the liquid adheres, during the substrate drying process performed using the substrate processing apparatus 1-4. The rotational speed of the substrate W is increased for a certain period of time, then reduced, and increased again for a certain period of time. This sequence is repeated to gradually increase the rotational speed, after which the substrate rotational speed is kept at a maximum level for a certain period of time. By thus controlling the rotational speed of the substrate W, the rate of reduction of the area of the portion of the surface of the substrate W to which the liquid adheres is kept equal to or smaller than a predetermined upper limit until the rate of reduction becomes nil.

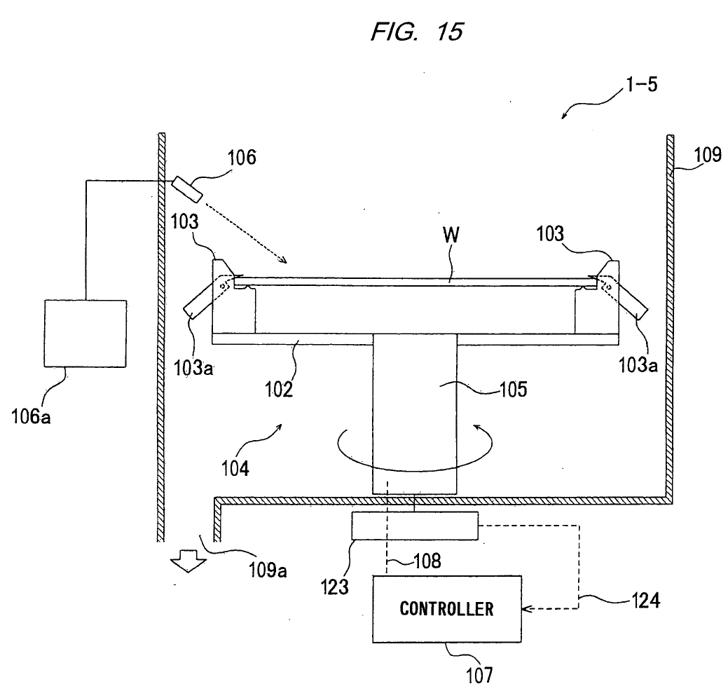

FIG. 15 shows a general structure of a substrate processing apparatus according to still another embodiment of the present invention. The substrate processing apparatus 1-5 shown in FIG. 15 differs from the substrate processing apparatus 1-1 shown in FIG. 7 in that the liquid droplet collector 111 and the mass meter 112 shown in FIG. 7 are replaced with a mass meter (monitor) 123 for measuring the mass of the substrate W and the substrate holder 104. The mass meter 123 measures the mass of the substrate W and the substrate holder 104 with high accuracy to measure a change in the mass of the liquid that adheres to the substrate W and the substrate holder 104. The mass meter 124 and the controller 107 are connected to each other by a control signal line 124, so that the mass measured by the mass meter 123 is sent by way of feedback to the controller 107.

In the substrate drying process, the substrate holder 104 is rotated to expel and remove the liquid adhering to the substrate W and the substrate holding mechanisms 103, whereupon the mass of the substrate W and the substrate holder 104 is thus gradually reduced. With the substrate processing apparatus 1-5, the mass meter 123 measures the mass of the substrate W and the substrate holder 104. The mass measured by the mass meter 123 is sent by way of feedback to the controller 107, which controls the rotational speed of the substrate holder 104 such that the amount of the liquid expelled from the substrate W and the substrate holder 104 is kept below a certain level. By thus sending the mass measured by the mass meter 123 by way of feedback to the controller 107, the rotational speed of the substrate W can be controlled such that the amount of the liquid scattered around from the substrate W and the substrate holder 104 is kept below a certain level. Therefore, as the substrate W can be rotated and dried while the amount of liquid droplets scattered around from the substrate holding mechanisms 103 and the substrate W is small in the substrate drying process, the liquid removed from the substrate W is prevented from splashing back to suppress the formation of water marks or the like.

FIG. 16 is a diagram showing the rotational speed (rpm) and rotational acceleration (rpm/s) of the substrate W with respect to the time (s) that has elapsed from the start of the substrate drying process, and the rate of reduction (g/s) of the mass of the substrate W and the substrate holder 104, during the substrate drying process performed using the substrate processing apparatus 1-4. The rotational speed of the substrate W is increased for a certain period of time, then reduced, and increased again for a certain period of time. This sequence is repeated to gradually increase the rotational speed, after which the substrate rotational speed is kept at a maximum level for a certain period of time. By thus controlling the rotational speed of the substrate W, the rate of reduction of the mass of the substrate W and the substrate holder 104 is kept equal to or smaller than a predetermined upper limit until the rate of reduction becomes nil.

FIG. 17 is a plan view showing an example of an arrangement of a CMP apparatus incorporating one or plural ones of the substrate processing apparatus 1-1 through 1-5 described above. The CMP apparatus 130 comprises substrate cassettes 131-1, 131-2, 131-3, 131-4, substrate transfer robots 132-1, 132-2, substrate processing apparatus 133-1, 133-2, 133-3, 133-4 each comprising either one of the substrate processing apparatus 1-1 through 1-5 described above according to the present invention, polishing modules (polishing apparatuses) 134-1, 134-2, and a temporary placing table 135. A cleaning chemical liquid supply device 136 is connected to the substrate processing apparatuses 133-1 through 133-4, and a slurry supply device 137 is connected to the polishing modules 134-1, 134-2. A controller 138 sends control signals to the various parts of the CMP apparatus 130.

In this CMP apparatus 130, based on a control signal outputted from the controller 138, the substrate transfer robot 132-1 takes one unprocessed substrate W out of either one of the substrate cassettes 131-1 through 131-4 and places the substrate W on the temporary placing table 135. The substrate W placed on the temporary placing table 135 is transferred to either one of the polishing modules 134-1, 134-2 where the substrate W is polished. Thereafter, the substrate W is transferred by the substrate transfer robot 132-2 successively to the substrate processing apparatus 133-1 through 133-4, which perform the chemical liquid processing process, the cleaning process, and the drying process of the substrate W. The chemical liquid and the cleaning liquid that are required by the substrate processing apparatus 133-1 through 133-4 are supplied from the cleaning chemical liquid supply device 136, and the slurry liquid required by the polishing modules 134-1, 134-2 is supplied from the slurry supply device 137.

With the CMP apparatus 130, the cleaning chemical liquid supply device 136, the slurry supply device 137, and an ancillary device such as a measuring instrument or the like (not shown) are controlled by control signals outputted from the controller 138. The controller 138 sends control signals to the various apparatus including the cleaning chemical liquid supply device 136, the slurry supply device 137, etc. to operate according to an input recipe. The control signals are applied to open and close valves (not shown) in a slurry supply line 140, a cleaning chemical liquid supply line 114, etc., and energize motors (not shown). It is possible to provide a flow rate sensor and apply a signal from the flow rate sensor to the controller 138, which performs a feedback control process to equalize the detected flow rate to a preset value, and also to shut down the apparatus if the detected flow rate falls outside of a preset range or the flow rate sensor outputs an abnormal signal. The controller 138 also controls the rotational speeds and rotational accelerations of the substrates, etc. in the substrate processing apparatuses 133-1 through 133-4. The cleaning chemical liquid supply device 136, the slurry supply device 137, the controller 138, and a display unit 139 and the like may be incorporated in the CMP apparatus 130.

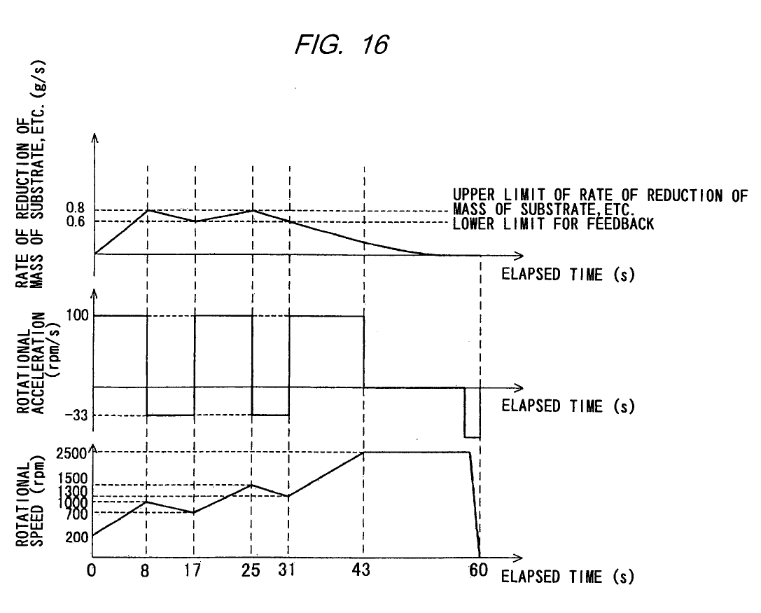

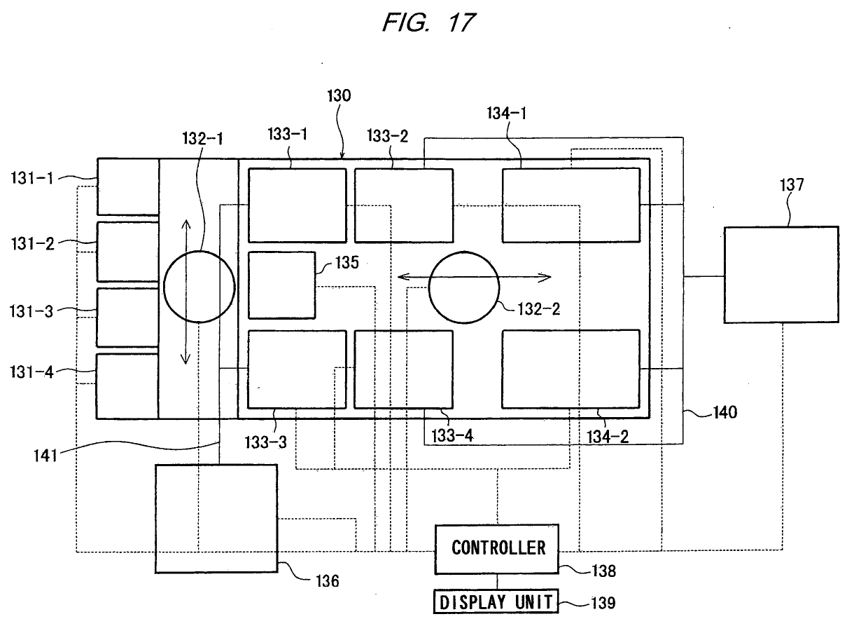

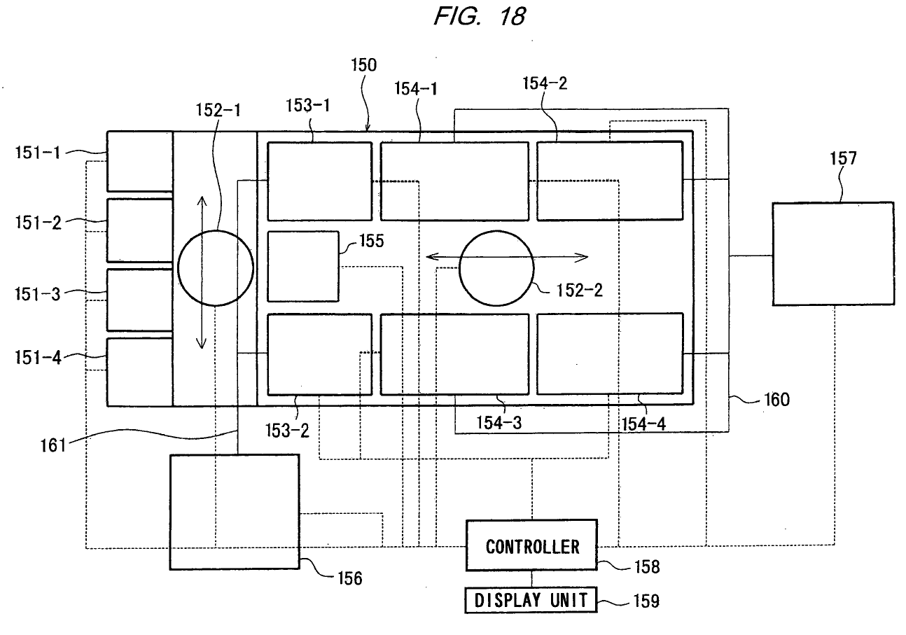

FIG. 18 is a plan view of an example of an arrangement of a plating apparatus incorporating the substrate processing apparatus described above. As shown in FIG. 18, the plating apparatus 150 comprises substrate cassettes 151-1, 151-2, 151-3, 151-4, substrate transfer robots 152-1, 152-2, substrate processing apparatuses 153-1, 153-2 each comprising either one of the substrate processing apparatuses 1-1 through 1-5 described above according to the present invention, plating tanks 154-1, 154-2, 154-3, 154-4, and a temporary placing table 155. A cleaning chemical liquid supply device 156 is connected to the substrate processing apparatuses 153-1, 153-2, and a plating chemical liquid supply device 157 is connected to the plating tanks 154-1, 154-2, 154-3, 154-4. A controller 158 sends control signals to the various parts of the plating apparatus 150.

In this plating apparatus 150, based on a control signal outputted from the controller 158, the substrate transfer robot 152-1 takes one unprocessed substrate W out of either one of the substrate cassettes 151-1 through 151-4 and places the substrate W on the temporary placing table 155. The substrate W placed on the temporary placing table 155 is transferred by the substrate transfer robot 152-2 to either one of the plating tanks 154-1 through 154-4 where the substrate W is plated. Thereafter, the substrate W is transferred by the substrate transfer robot 152-2 to either one of the substrate processing apparatus 153-1, 153-2 where the cleaning process and the drying process of the substrate W are performed. The plating solution that is required by the plating tanks 154-1 through 154-4 is supplied from the plating chemical liquid supply device 157, and the cleaning liquid required by the substrate processing apparatus 153-1, 153-2 is supplied from the cleaning chemical liquid supply device 156.

With the plating apparatus 150, the cleaning chemical liquid supply device 156, the plating chemical liquid supply device 157, and an ancillary device such as a measuring instrument or the like (not shown) are controlled by control signals outputted from the controller 158. The controller 158 sends control signals to the various apparatus including the cleaning chemical liquid supply device 156, the plating chemical liquid supply device 157, etc. to operate according to an input recipe. The control signals are applied to open and close valves (not shown) in a plating solution supply line 160, a cleaning liquid supply line 161, etc., and energize motors (not shown). It is possible to provide a flow rate sensor and apply a signal from the flow rate sensor to the controller 158, which performs a feedback control process to equalize the detected flow rate to a preset value, and also to shut down the apparatus if the detected flow rate falls outside of a preset range or the flow rate sensor outputs an abnormal signal. The controller 158 also controls the rotational speeds and rotational accelerations of the substrates, etc. in the substrate processing apparatuses 153-1, 153-2. The cleaning chemical liquid supply device 136, the plating chemical liquid supply device 157, the controller 158, and a display unit 159, and the like may be incorporated in the plating apparatus 150.

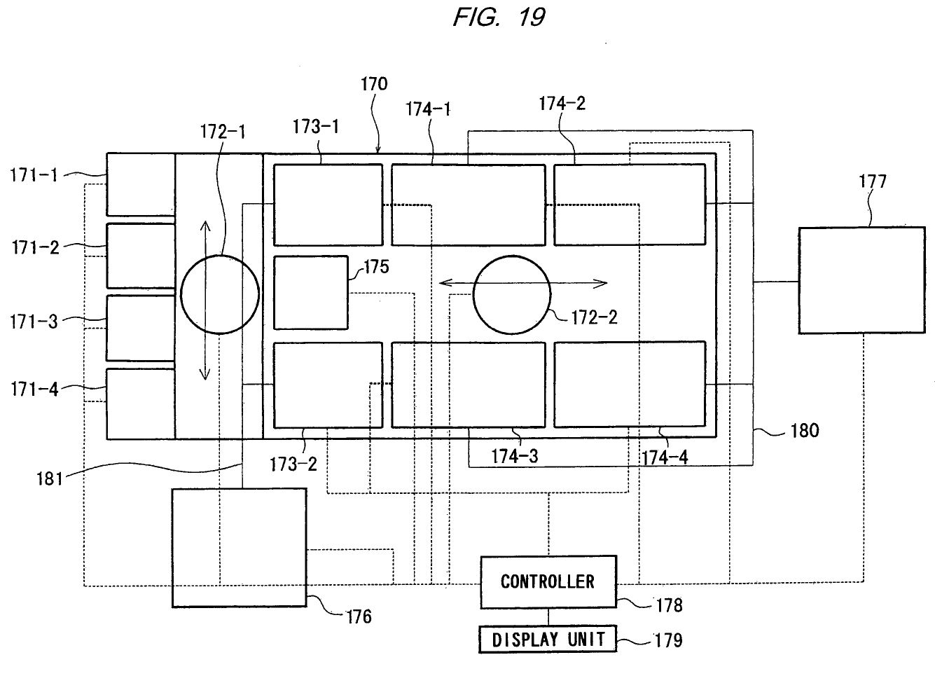

FIG. 19 is a plan view of an example of an arrangement of a cleaning apparatus incorporating the substrate processing apparatus described above. As shown in FIG. 19, the plating apparatus 170 comprises substrate cassettes 171-1, 171-2, 171-3, 171-4, substrate transfer robots 172-1, 172-2, substrate processing apparatuses 173-1, 173-2 according to the present invention, roll cleaning units 174-1, 174-2, 174-3, 174-4, and a temporary placing table 175. A cleaning chemical liquid supply device 176 is connected to the substrate processing apparatuses 173-1, 173-2, and an ultrapure water supply device 177 is connected to the roll cleaning units 174-1, 174-2, 174-3, 174-4. A controller 178 sends control signals to the various parts of the cleaning apparatus 170.

In this cleaning apparatus 170, based on a control signal outputted from the controller 178, the substrate transfer robot 172-1 takes one unprocessed substrate W out of either one of the substrate cassettes 171-1 through 171-4 and places the substrate W on the temporary placing table 175. The substrate W placed on the temporary placing table 175 is transferred by the substrate transfer robot 172-2 to either one of the roll cleaning units 174-1 through 174-4 where roll cleaning of the substrate W is performed. Thereafter, the substrate W is transferred by the substrate transfer robot 152-2 to either one of the substrate processing apparatuses 173-1, 173-2 where the cleaning process and the drying process of the substrate W is performed. The ultrapure water required by the roll cleaning units 174-1 through 174-4 is supplied from the ultrapure water supply device 177, and the chemical liquid and the cleaning liquid required by the substrate processing apparatus 173-1, 173-2 is supplied from the cleaning chemical liquid supply device 176.

With the cleaning apparatus 170, the cleaning chemical liquid supply device 176, the ultrapure water supply device 177, and an ancillary device such as a measuring instrument or the like (not shown) are controlled by control signals outputted from the controller 178. The controller 178 sends control signals to the various apparatus including the cleaning chemical liquid supply device 176, the ultrapure water supply device 177, etc. to operate according to an input recipe. The control signals are applied to open and close valves (not shown) in an ultrapure water supply line 180, a cleaning liquid supply line 181, etc., and energize motors (not shown). It is possible to provide a flow rate sensor and apply a signal from the flow rate sensor to the controller 178, which performs a feedback control process to equalize the detected flow rate to a preset value, and also to shut down the apparatus if the detected flow rate falls outside of a preset range or the flow rate sensor outputs an abnormal signal. The controller 178 also controls the rotational speeds and rotational accelerations of the substrates, etc. in the substrate processing apparatuses 173-1, 173-2. The cleaning chemical liquid supply device 136, the ultrapure water supply device 177, the controller 178, and a display unit 179, and the like may be incorporated in the cleaning apparatus 170.

The substrate processing processes performed by the substrate processing apparatuses 1-1 through 1-5 described in the above embodiments are not limited to those described above. The substrate processing apparatus may be arranged to process the substrate W depending on its type by changing the installed position of the processing liquid supply nozzle 106, the types of the cleaning liquid and the chemical liquid supplied therefrom, and the timing at which they are supplied. Specifically, in each of the illustrated substrate processing apparatuses 1-1 through 1-5, the processing liquid supply nozzle 106 is installed above the substrate W, and supplies the substrate processing liquid to the upper surface of the substrate W. However, a processing liquid supply section may be installed below or laterally of the substrate W for supplying a processing liquid to the lower surface or side of the substrate W. While the image capturing camera 120 is shown as being installed in a position to image the upper surface of the substrate W, the image capturing camera 120 is not limited to the illustrated installed position, but may be installed in a position to image the lower surface or side of the substrate W.

With the substrate processing apparatuses 1-1 through 1-5, as shown in FIGS. 8, 10, 12, 14, and 16, predetermined upper and lower limits may be provided, and the controller 107 may control the rotational speed of the substrate holder 104 such that when the measured value exceeds the upper limit, the rotational speed of the substrate W is reduced, and when the measured value is lower than the lower limit, the rotational speed of the substrate W is increased. To prevent the measured value from greatly overshooting the upper limit, the rotational acceleration of the substrate W may be set to a lower value (which is desirably equal to or lower than 300 rpm/s (5 sec⁻²)) in an initial accelerating period than in a subsequent accelerating period, and then may be set to a higher value (which is desirably equal to or lower than 500 rpm/s (about 8.3 sec⁻²)) in the subsequent accelerating period.

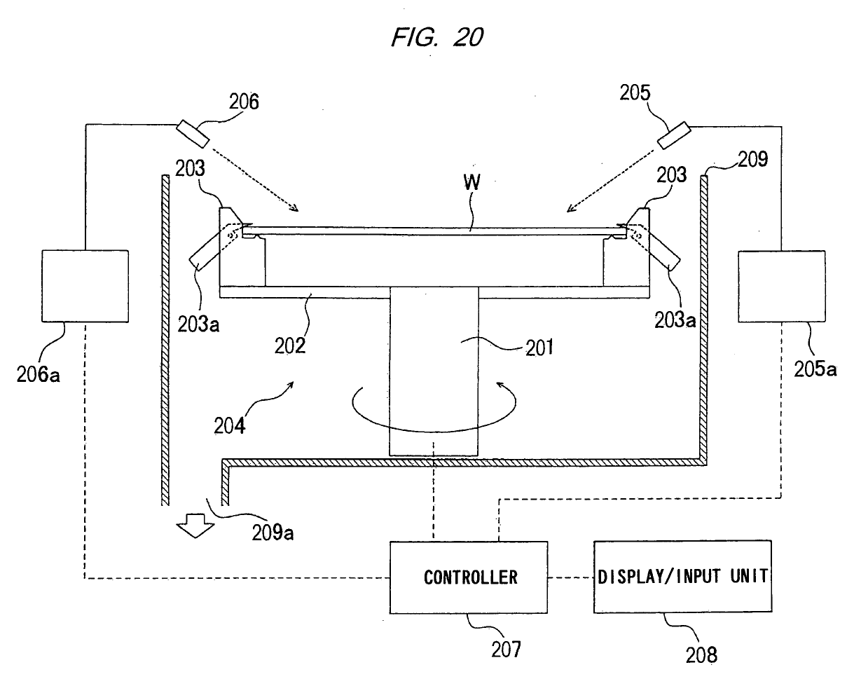

FIG. 20 shows a general structure of a substrate processing apparatus according to still another embodiment of the present invention. The substrate processing apparatus has a rotational shaft 201 and a substrate holder 204. The substrate holder 204 has a plurality of bases 202 extending radially outwardly horizontally from the upper end of the rotational shaft 201, and substrate holding mechanisms 203 mounted on the distal ends of the bases 202. The bases 202 and the substrate holding mechanisms 203 are provided in a plurality of sets (three or more sets). A substrate W such as a semiconductor wafer or the like to be processed is placed centrally on the substrate holding mechanisms 203, and gripped by substrate pressers 203a of the substrate holding mechanisms 203. The rotational shaft 201 is coupled to an actuator (not shown). With the substrate W held by the substrate holding mechanisms 203, the substrate holder 204 is rotated about the rotational shaft 201. The actuator accelerates/decelerates the substrate holder 204 at a desired acceleration and rotates the substrate holder 204 at a target rotational speed.

A cleaning liquid supply nozzle 205 for supplying a cleaning liquid to the surface of the substrate W and a chemical liquid supply nozzle 206 for supplying a chemical liquid to the surface of the substrate W are disposed above the substrate holder 204. The rates, etc. of the cleaning liquid and the chemical liquid supplied from the cleaning liquid supply nozzle 205 and the chemical liquid supply nozzle 206 are regulated by a cleaning liquid supply system 205a that is connected to the cleaning liquid supply nozzle 205 and a chemical liquid supply system 206a that is connected to the chemical liquid supply nozzle 206. The cleaning liquid supply system 205a and the chemical liquid supply system 206a are connected to a controller 207 by control signal lines, and are controlled by control signals from the controller 207. A display/input unit 208 is connected to the controller 207.

A scattering prevention cup 209 for preventing the processing liquid supplied to the substrate W from being scattered around is disposed around the side of the substrate holder 204. The scattering prevention cup 209 receives the processing liquid scattered from the substrate holding mechanisms 203 and the substrate W, and discharges the processing liquid from a waste liquid drain port 209a defined in a lower portion thereof. The substrate cleaning liquid used to rinse the substrate W generally comprises DIW (pure water) or gas-dissolved water. Depending on the purpose, the substrate W may be cleaned using another chemical liquid.

The substrate processing apparatus shown in FIG. 20 can successively perform a substrate processing process using a chemical liquid, a substrate cleaning process, and a drying process. In each of these processes, the rotational speed and rotational acceleration of the substrate, and timings to supply the chemical liquid and the cleaning liquid, etc. are determined by being controlled by the controller 207 according to a program inputted from the display/input unit 208. The procedure of the processing process using a chemical liquid, the cleaning process, and the drying process of the substrate will simply be described below. First, the substrate W to be processed is placed centrally on the substrate holding mechanisms 203 by a robot hand or the like (not shown), and then gripped by the substrate pressers 203a. Thereafter, the substrate holder 204 is rotated to rotate the substrate W. Then, a chemical liquid is supplied from the chemical liquid supply nozzle to the substrate W to process the substrate W with the chemical liquid (the substrate processing process). Then, while the substrate W is being rotated, a cleaning liquid such as DIW or the like is supplied from the cleaning liquid supply nozzle 205 to the substrate W to clean (rinse) the substrate W (the substrate cleaning process) When the substrate cleaning process is finished, the substrate W is rotated at a high speed to expel and remove the substrate processing liquid, such as the cleaning liquid or the like, adhering to the substrate W, thus drying the substrate W (the substrate drying process).

FIG. 21 shows an example of a profile of substrate rotational speeds in the above substrate processing process. In this example, the chemical liquid processing process and the cleaning process are performed at a substrate rotational speed of 500 rpm, and the substrate rotational speed is increased according to a quadratic function of the elapsed time in the drying process. If the starting time of the substrate drying process is zero, the elapsed time is represented by X(s), and the substrate rotational speed by Y (rpm), then the profile of substrate rotational speeds in the substrate drying process is expressed by the equation (1) shown below. It is assumed that the maximum substrate rotational speed in the substrate drying process is 3500 rpm, and the maximum value of the rotational acceleration of the substrate is a rotational acceleration of 100 rpm/s (about 1.7 sec⁻²) at X=20(s).
Y=A(X−B)²+C (1)

(When 0≦X≦20, A=2.5 rpm/s², B=0, and C=500 rpm; when 20<X≦40, A=−2.5 rpm/s², B=40s, and C=3500 rpm; and when 40<X≦50, Y=3500.)

By gradually increasing the rotational acceleration of the substrate as the quadratic function of the elapsed time and keeping the rotational acceleration equal to or less than a predetermined value, the liquid adhering to the substrate can be removed without being scattered around, and the liquid removed from the substrate is prevented from splashing back to suppress the formation of water marks or the like. The processing time of the substrate drying process can be shortened by reducing the maximum rotational speed of the substrate. Furthermore, the entrapment of air streams due to the rotation of the substrate can be reduced to suppress the formation of defects on the substrate.

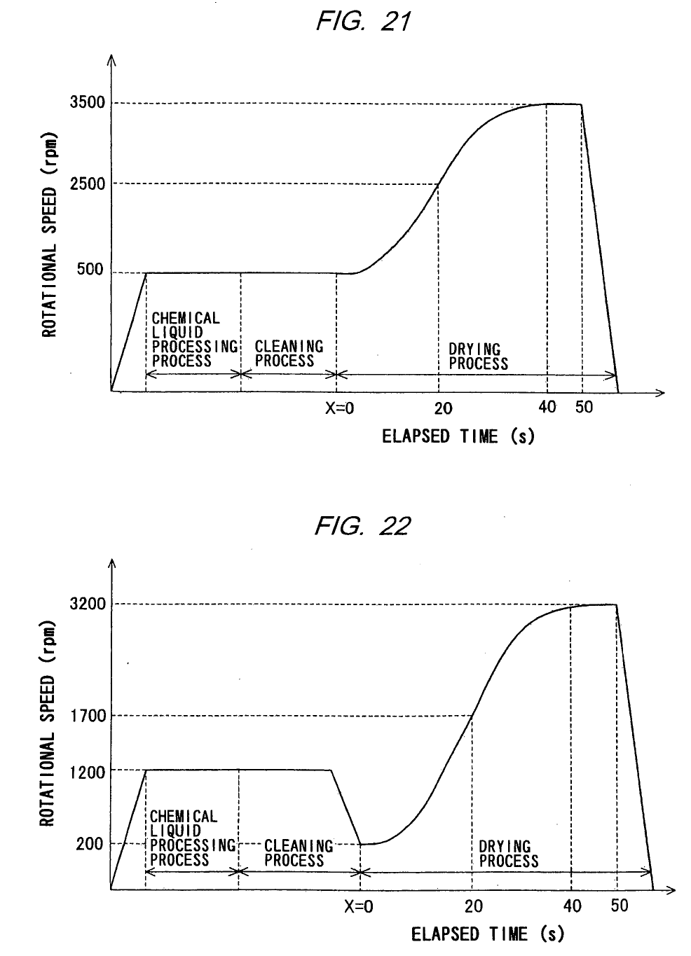

FIG. 22 shows another example of a profile of substrate rotational speeds in the substrate processing process. In this example, the chemical liquid processing process and the cleaning process are performed at a substrate rotational speed of 1200 rpm, and the substrate rotational speed is reduced to 200 rpm at the end of the cleaning process. At the start of the substrate drying process, the substrate rotational speed is 200 rpm, and the substrate rotational speed is subsequently increased according to a quadratic function of the elapsed time. If the starting time of the substrate drying process is zero, the elapsed time is represented by X(s), and the substrate rotational speed by Y (rpm), then the profile of substrate rotational speeds in the substrate drying process is expressed by the equation (2) shown below. It is assumed that the maximum substrate rotational speed in the substrate drying process is 3200 rpm, and the maximum value of the rotational acceleration of the substrate is 150 rpm/s (2.5 sec⁻²) at X=20(s).
Y=A·(X−B)²+C (2)

(When 0≦X≦20, A=3.75 rpm/s², B=0, and C=200 rpm; when 20<X≦40, A=−3.75 rpm/s², B=40s, and C=3200 rpm; and when 40<X≦50, Y=3200.)

Since the substrate rotational speed at the start of the substrate drying process is held to a low value (500 rpm or less), the liquid adhering to the substrate can be removed without being scattered around, and the liquid removed from the substrate is prevented from splashing back to suppress the formation of water marks or the like.

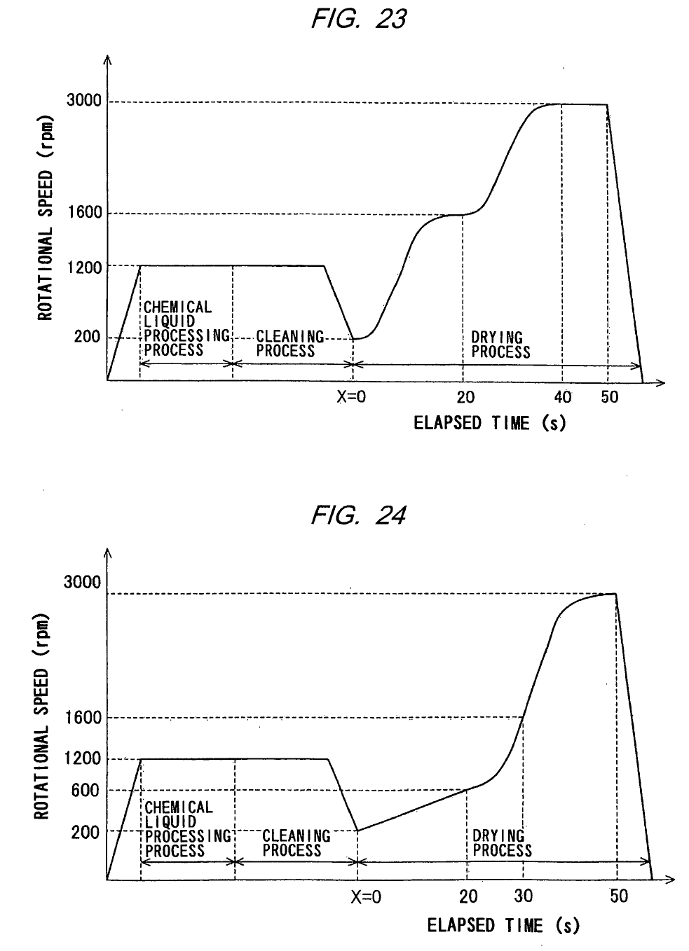

FIG. 23 shows still another example of a profile of substrate rotational speeds in the substrate processing process. In this example, the chemical liquid processing process and the cleaning process are performed at a substrate rotational speed of 1200 rpm, and the substrate rotational speed is reduced to 200 rpm at the end of the cleaning process. The substrate rotational speed is subsequently increased according to a quadratic function of the elapsed time. If the starting time of the substrate drying process is zero, the elapsed time is represented by X(s), and the substrate rotational speed by Y (rpm), then the profile of substrate rotational speeds in the substrate drying process is expressed by the equation (3) shown below. It is assumed that the maximum substrate rotational speed in the substrate drying process is 3000 rpm, and the maximum value of the rotational acceleration of the substrate is 140 rpm/s (about 2.3 sec⁻²) at X=10(s) and 30(s).
Y=A·(X−B)²+C (3)

(When 0≦X≦10, A=7.0 rpm/s², B=0, and C=200 rpm; when 10<X≦20, A=−7.0 rpm/s², B=20s and C=1600 rpm; when 20<X≦30, A=7.0 rpm/s², B=20s, and C=1600 rpm; when 30<X≦40, A=−7.0 rpm/s², B=40s, and C=3000 rpm; and when 40<X≦50, Y=3000.)

FIG. 24 shows still another example of a profile of substrate rotational speeds in the substrate processing process. In this example, the chemical liquid processing process and the cleaning process are performed at a substrate rotational speed of 1200 rpm, and the substrate rotational speed is reduced to 200 rpm at the end of the cleaning process. At the start of the substrate drying process, the substrate rotational speed is 200 rpm, and the substrate rotational speed is subsequently increased linearly with respect to the elapsed time until the elapsed time reaches 20 (s), and then increased according to a quadratic function of the elapsed time. If the starting time of the substrate drying process is zero, the elapsed time is represented by X(s), and the substrate rotational speed by Y (rpm), then the profile of substrate rotational speeds in the substrate drying process is expressed by the equations (4), (5) shown below. It is assumed that the maximum substrate rotational speed in the substrate drying process is 3000 rpm, and the maximum value of the rotational acceleration of the substrate is 40 rpm/s (about 0.7 sec⁻²) at X=30(s).
Y=A·X+B (4)

(When 0≦X≦20, A=20.0 rpm/s, B=200 rpm)
Y=C·(X−D)²+E (5)

(When 20<X≦30, C=1.0 rpm/s², D=10s, and E=1200 rpm; and when 30<X≦50, C=−1.0 rpm/s², D=50s, and E=3000 rpm.)

FIG. 25 shows still another example of a profile of substrate rotational speeds in the substrate processing process. In this example, the chemical liquid processing process and the cleaning process are performed at a substrate rotational speed of 600 rpm, and the substrate rotational speed is reduced to 600 rpm at the end of the cleaning process. The substrate rotational speed is increased linearly with respect to the elapsed time from the start of the substrate drying process. It is assumed that the maximum substrate rotational speed in the substrate drying process is 3000 rpm, and the rotational acceleration of the substrate is constant at 80 rpm/s (about 1.3 sec⁻²).

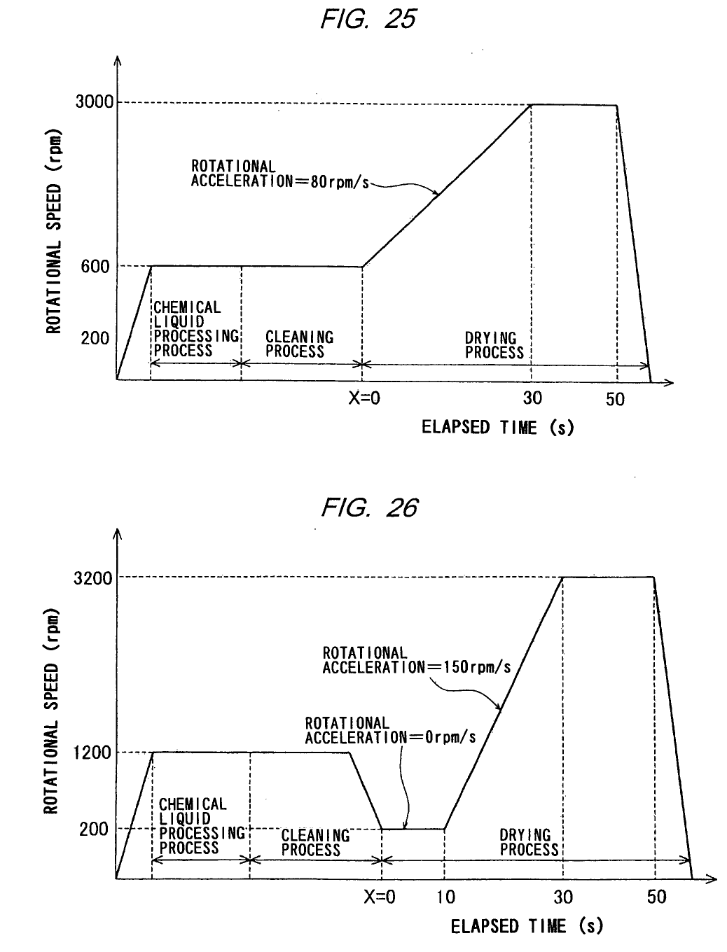

FIG. 26 shows still another example of a profile of substrate rotational speeds in the substrate processing process. In this example, the chemical liquid processing process and the cleaning process are performed at a substrate rotational speed of 1200 rpm, and the substrate rotational speed is reduced to 200 rpm at the end of the cleaning process. At the start of the substrate drying process, the substrate rotational speed is 200 rpm, and the substrate rotational speed is subsequently increased linearly with respect to the elapsed time. It is assumed that the maximum substrate rotational speed in the substrate drying process is 3200 rpm, and the rotational acceleration of the substrate is constant at 100 rpm/s (about 1.7 sec⁻²).

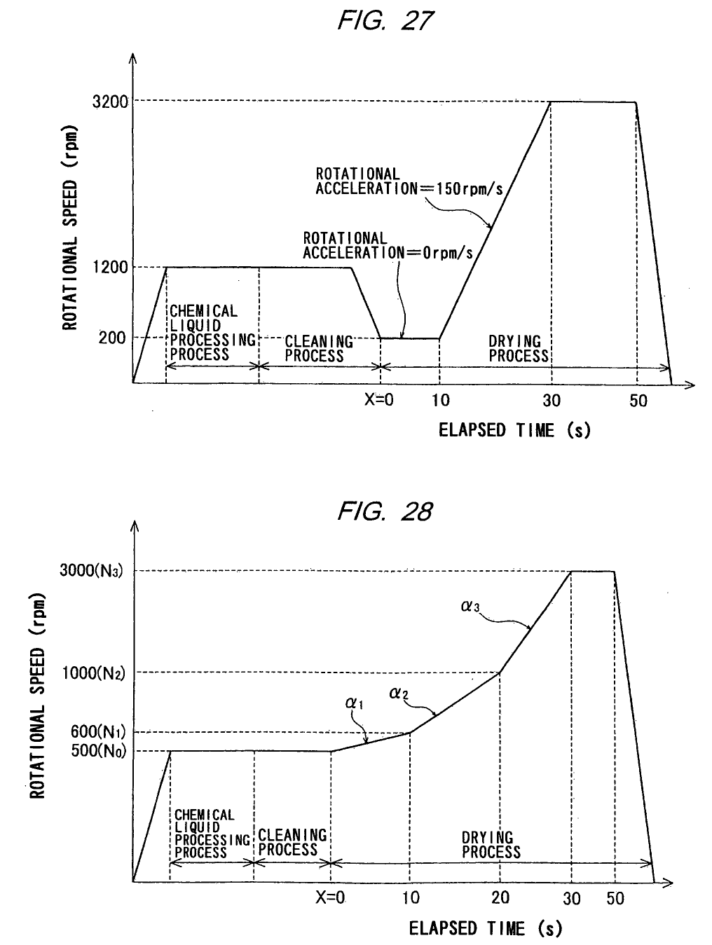

FIG. 27 shows still another example of a profile of substrate rotational speeds in the substrate processing process. In this example, the chemical liquid processing process and the cleaning process are performed at a substrate rotational speed of 1200 rpm, and the substrate rotational speed is reduced to 200 rpm at the end of the cleaning process. At the start of the substrate drying process, the substrate rotational speed is 200 rpm, and the substrate rotational speed is subsequently zero from the start of the substrate drying process until the elapsed time reaches 10 (s), and thereafter is constant at 150 rpm/s (2.5 sec⁻²).

FIG. 28 shows still another example of a profile of substrate rotational speeds in the substrate processing process. In this example, the chemical liquid processing process and the cleaning process are performed at a substrate rotational speed of 500 rpm. In the substrate drying process, a first rotational acceleration α₁ is 10 rpm/s (α₁=10 rpm/s (about 0.17 sec⁻²)) until the substrate rotational speed changes from N₀=500 rpm (initial rotational speed) at the start of the substrate drying process to a first rotational speed N₁=600 rpm, a second rotational acceleration α₂ is 30 rpm/s (α₂=30 rpm/s (0.5 sec⁻²)) until the substrate rotational speed changes from the first rotational speed N₁ to a second rotational speed N₂=1000 rpm, and a third rotational acceleration α₃ is 200 rpm/s (α₃=200 rpm/s (about 3.3 sec⁻²)) until the substrate rotational speed changes from the second rotational speed N₂ to a third rotational speed N₃=3000 rpm. Specifically, the substrate rotational speed in the substrate drying process is changed in multiple steps and successively increased in those steps, and so is the rotational acceleration. By thus changing the substrate rotational speed, the liquid, which adheres to the substrate while the rotational speed is being slowly and gradually increased from a low rotational speed at a low rotational acceleration, can be removed without being scattered around. This can prevent the liquid droplets removed from the substrate from splashing back to suppress the formation of water marks or the like. Since the liquid adhering to the substrate can efficiently be removed, the maximum rotational speed of the substrate can be held to a low value. In addition, as the period of time for which the maximum rotational speed is kept is shortened, the time of the drying process is shortened.

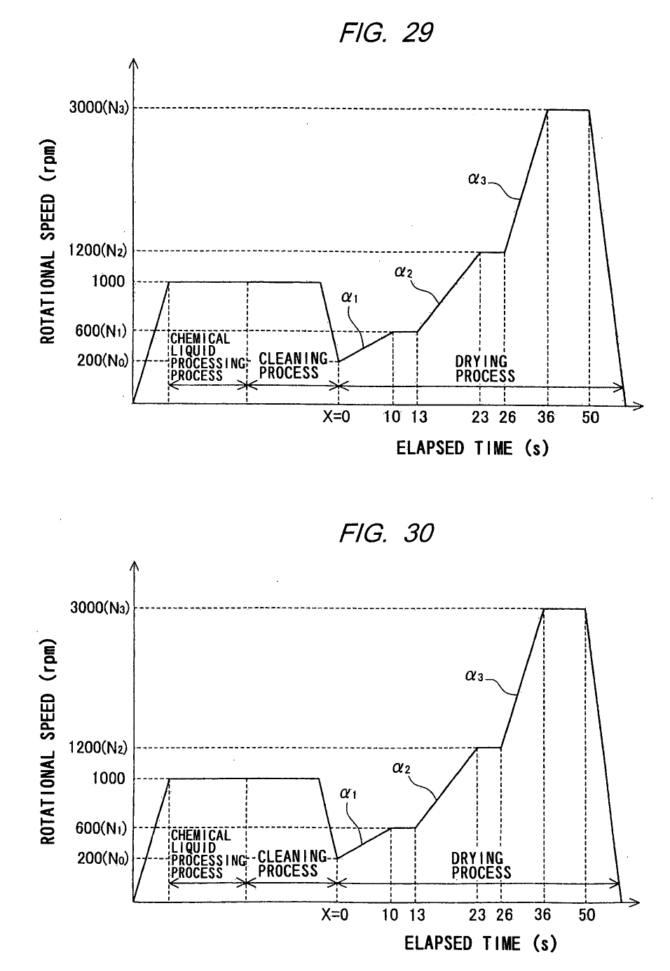

FIG. 29 shows still another example of a profile of substrate rotational speeds in the substrate processing process. In this example, the chemical liquid processing process and the cleaning process are performed at a substrate rotational speed of 1000 rpm. At the end of the substrate cleaning process, the substrate rotational speed is reduced to 200 rpm. The substrate rotational speed (initial rotational speed) at the start of the substrate drying process is N₀=200 rpm. A first rotational acceleration α₁ is 40 rpm/s (α₁=40 rpm/s (about 0.67 sec⁻²)) until the substrate rotational speed changes from N₀ to a first rotational speed N₁=600 rpm, a second rotational acceleration α₂ is 60 rpm/s (α₂=60 rpm/s (1 sec⁻²)) until the substrate rotational speed changes from the first rotational speed N₁ to a second rotational speed N₂=1200 rpm, and a third rotational acceleration α₃ is 180 rpm/s (α₃=180 rpm/s (about 3 sec⁻²)) until the substrate rotational speed changes from the second rotational speed N₂ to a third rotational speed N₃=3000 rpm. Specifically, the substrate rotational speed in the substrate drying process is changed in multiple steps and successively increased in those steps, and so is the rotational acceleration.

FIG. 30 shows still another example of a profile of substrate rotational speeds in the substrate processing process. In this example, the chemical liquid processing process and the cleaning process are performed at a substrate rotational speed of 1000 rpm. At the end of the substrate cleaning process, the substrate rotational speed is reduced to 200 rpm. The substrate rotational speed (initial rotational speed) at the start of the substrate drying process is N₀=200 rpm. A first rotational acceleration α₁ is 40 rpm/s (α₁=40 rpm/s (about 0.67 sec⁻²)) until the substrate rotational speed changes from N₀ to a first rotational speed N₁=600 rpm. After the substrate rotational speed reaches the first rotational speed N₁, the substrate rotational speed is maintained for 3 seconds. Thereafter, a second rotational acceleration α₂ is 60 rpm/s (α₂=60 rpm/s (1 sec⁻²)) until the substrate rotational speed changes from the first rotational speed N₁ to a second rotational speed N₂=1200 rpm. The substrate rotational speed is maintained for 3 seconds. Thereafter, a third rotational acceleration α₃ is 180 rpm/s (α₃=180 rpm/s (about 3 sec⁻²)) until the substrate rotational speed changes from the second rotational speed N₂ to a third rotational speed N₃=3000 rpm. Specifically, the substrate rotational speed in the substrate drying process is changed in multiple steps and successively increased in those steps, and so is the rotational acceleration.

FIG. 31 shows still another example of a profile of substrate rotational speeds in the substrate processing process. In this example, the chemical liquid processing process and the cleaning process are performed at a substrate rotational speed of 500 rpm. At the end of the substrate cleaning process, the substrate rotational speed is reduced to 200 rpm. From the start of the substrate drying process until the elapsed time reaches 10 (s), the rotational acceleration is zero. Thereafter, the rotational acceleration is constant at 45 rpm/s (0.75 sec⁻²). The maximum rotational speed of the substrate is 1100 rpm. According to this substrate rotational speed profile, the liquid is efficiently removed while the rotational speed is being slowly and gradually increased from a low rotational speed at a low rotational acceleration. Though the maximum rotational speed is of a low level of 1100 rpm and is held for a short time of 2 seconds, the liquid adhering to the surface of the substrate is sufficiently removed.

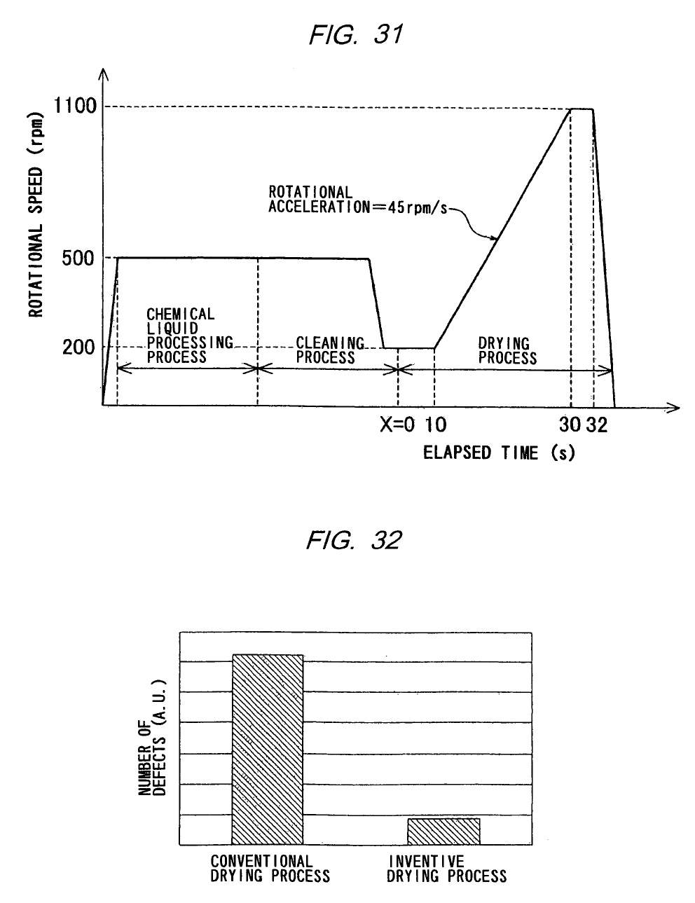

FIG. 32 shows a measured increase in the number of defects on the surface of a silicon substrate having a diameter of 200 mm after the substrate is processed successively in the chemical liquid processing process, the cleaning process, and the drying process according to the substrate rotational speed profile shown in FIG. 31. FIG. 32 also shows comparative data representing the measured number of defects produced when the substrate is dried by a conventional drying process in which the rotational acceleration is more than 500 rpm/s (about 8.3 sec⁻²). As can be seen from FIG. 32, the number of defects on the surface of the substrate which is dried in the substrate drying process according to the present invention is reduced to about 1/7 of the number of defects on the surface of the substrate which is dried in the conventional substrate drying process. According to this substrate rotational speed profile, since the rotational acceleration is lowered, the chemical liquid adhering to the surface of the substrate can sufficiently be removed without splashing back when the substrate rotational speed is increased. Therefore, even if the maximum rotational speed in the substrate drying process is set to 1200 rpm or less and the maximum rotational speed is maintained for 5 (s) or less, these values being smaller than those in the conventional substrate drying process, the substrate can sufficiently be dried.

According to the conventional substrate drying process disclosed in Japanese laid-open patent publication No. 2003-92280, the time except for the time to increase the substrate rotational speed in the substrate drying process is in the range from 18 seconds to 47 seconds. In view of the fact that the time required to increase the substrate rotational speed is added to the above time (e.g., 10 (s) is required to increase the substrate rotational speed from 200 rpm to 3400 rpm at an acceleration of 320 rpm/s (about 5.3 sec⁻²)), the drying time in the substrate drying process according to the present invention is shorter than the drying time in the substrate drying process disclosed in Japanese laid-open patent publication No. 2003-92280.

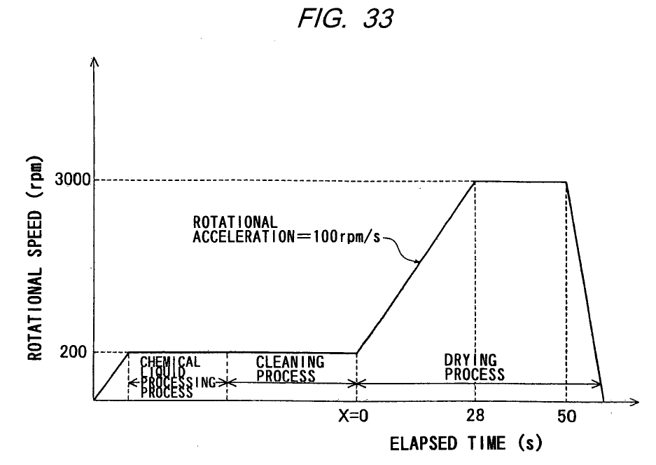

FIG. 33 shows still another example of a profile of substrate rotational speeds in a substrate processing process. In this example, the chemical liquid processing process and the cleaning process are performed at a substrate rotational speed of 200 rpm. At the end of the substrate cleaning process and the start of the substrate drying process, the substrate rotational speed is 200 rpm. The substrate rotational speed is subsequently increased linearly with respect to the elapsed time. The maximum substrate rotational speed is 3000 rpm, and the rotational acceleration is constant at 100 rpm/s (about 1.7 sec⁻²). According to this substrate rotational speed profile, since the substrate rotational speed is low in the chemical liquid processing process and the cleaning process, the cleaning liquid supply nozzle 205 for supplying the cleaning liquid to the substrate and the chemical liquid supply nozzle 206 for supplying the chemical liquid to the substrate shown in FIG. 20 are preferably installed in two or more locations each, for thereby increasing the amounts of the chemical liquid and the cleaning liquid supplied to the substrate, so that the chemical liquid and the DIW are distributed in sufficient amounts to the entire surface of the substrate.

The substrate processing apparatus shown in FIG. 20 may be used as the substrate processing apparatus 131-1, 131-2, 131-3, 131-4 of the CMP apparatus 130 shown in FIG. 17, or the substrate processing apparatus 153-1, 153-2 of the plating apparatus 150 shown in FIG. 18, or substrate processing apparatus 173-1, 173-2 of the cleaning apparatus 170 shown in FIG. 19.

In the substrate processing process performed by the substrate processing apparatus shown in FIG. 20, the substrate W can be processed depending on its type by changing the installed positions of the cleaning liquid supply nozzle 205 and the chemical liquid supply nozzle 206, the types of the cleaning liquid and the chemical liquid supplied therefrom, and the timing at which they are supplied. The substrate rotational speed profiles used in the above substrate processing processes are shown by way of example only, and the substrate processing method according to the present invention are not limited to those substrate rotational speed profiles.

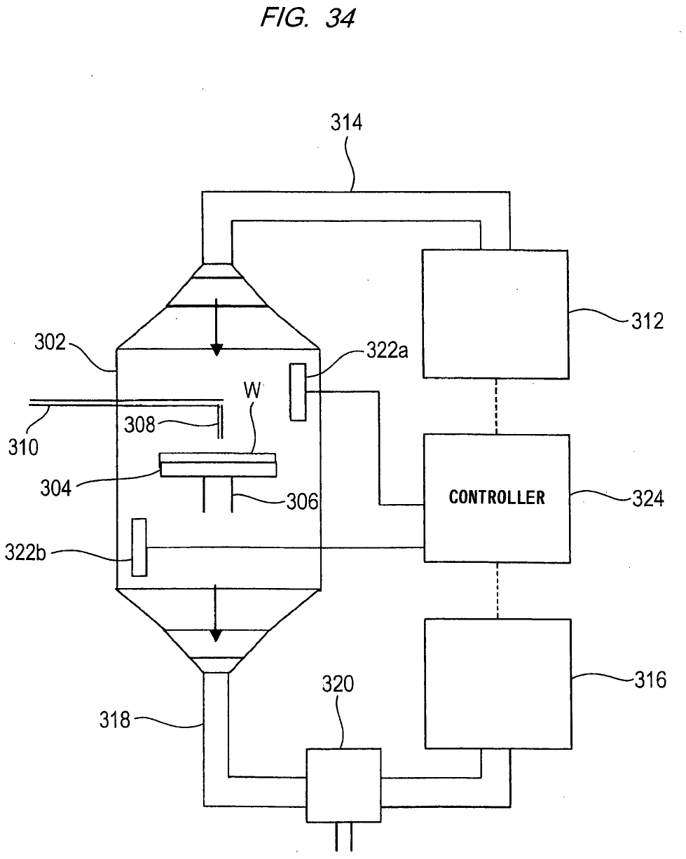

FIG. 34 shows a substrate processing apparatus according to still another embodiment of the present invention. The substrate processing apparatus has a processing chamber 302 that can be closed, and a substrate holder 304 disposed in the processing chamber 302 for detachably holding a substrate W with its surface facing upwardly. The substrate holder 304 is coupled to the upper end of a rotational shaft 306 which is rotatable and capable of adjusting its rotational speed and/or rotational acceleration. A processing liquid supply nozzle 308 for supplying a processing liquid, such as a chemical liquid, a cleaning liquid, or the like, to the surface of the substrate W is disposed above the substrate holder 304. The processing liquid supply nozzle 308 is connected to a processing liquid supply line 310 which extends from outside of the processing chamber 304 into the processing chamber 304.

The processing chamber 302 has a top connected to a dry gas supply pipe (dry gas supply section) 314 extending from a dry gas supply device 312 and a bottom connected to an air discharge pipe 318 extending from an air discharge device 316. The discharge pipe 314 has a water separating tank 320. The dry gas supply device 312 supplies, for example, a dry gas comprising an inactive gas or air whose relative humidity is controlled in the range from 0 to 30%, as described above, through the dry gas supply pipe 314 into the processing chamber 302, thus making up a drying section for promoting the evaporation of a liquid that adheres to the substrate that is held by the substrate holder 304.

A first humidity sensor (monitor) 322a is positioned above the substrate W that is held by the substrate holder 304 in the processing chamber 302, for measuring the humidity above the substrate W. A second humidity sensor (monitor) 322b is positioned below the substrate W that is held by the substrate holder 304, for measuring the humidity below the substrate W. The humidity sensors 322a, 322b input respective output signals as feedback signals to a controller 324, which inputs an output signal thereof to the dry gas supply device 312 and the discharge device 316 as the drying section. The dry gas supply device 312 and the discharge device 316 are controlled by control signals from the controller 324 to equalize the flow rate of the dry gas and the humidity in the processing chamber 302 and the amount of discharged air from the processing chamber 302 to preset values.

In this embodiment, the dry gas is used in the drying section, and the humidity in the processing chamber is measured by the humidity sensor as the monitor. However, the dew point and temperature in the processing chamber may be monitored (measured), and may be controlled to reach respective preset values.

The substrate processing apparatus shown in FIG. 20 can successively perform a processing process using a chemical liquid of a substrate, a cleaning process, and a drying process, as with the previous embodiments.

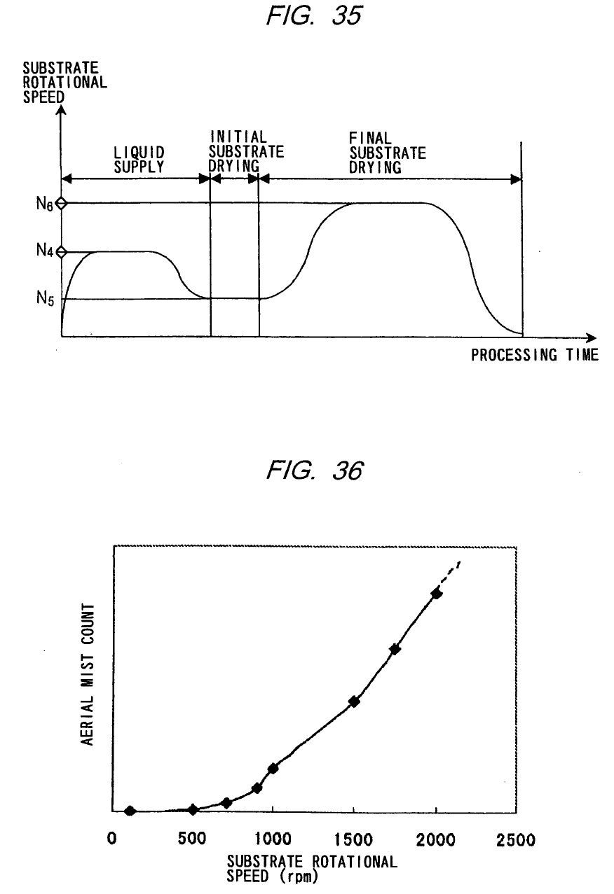

FIG. 35 shows an example of a profile of substrate rotational speeds in the substrate processing process described above. In this example, while the substrate W is being rotated at a rotational speed N₄, a processing liquid is supplied to the surface of the substrate to process the substrate with the chemical liquid. After the supply of the processing liquid is stopped, the substrate is rotated at an initial rotational speed N₅ of 1000 rpm or less, and at the same time a dry gas of a low humidity is supplied into the processing chamber, as described above, to initially dry the substrate, thereby removing the liquid on the substrate to a certain extent. Thereafter, while a dry gas of a low humidity is being supplied into the processing chamber, the rotational speed of the substrate is changed stepwise or continuously to reduce the amount of liquid on the substrate. Then, the substrate W is rotated at a maximum rotational speed N₆ of 800 rpm or higher to evaporate the liquid on the substrate, after which the rotational speed of the substrate is reduced to 0 rpm, thereby finishing the drying of the substrate.

FIG. 36 shows the relationship between the rotational speed of a substrate wetted by a processing liquid when the substrate is rotated and the aerial mist count. It can be understood from FIG. 36 that the aerial mist count is smaller as the substrate rotational speed is lower, and such a phenomenon manifests itself when the rotational speed of the substrate is 1000 rpm or lower. Therefore, while the substrate is being rotated at an initial rotational speed N₅ of 1000 rpm or less, a dry gas of a low humidity is supplied into the processing chamber, if necessary, thus initially drying the substrate to greatly reduce the aerial mist count in the atmosphere near the substrate which is being rotated.

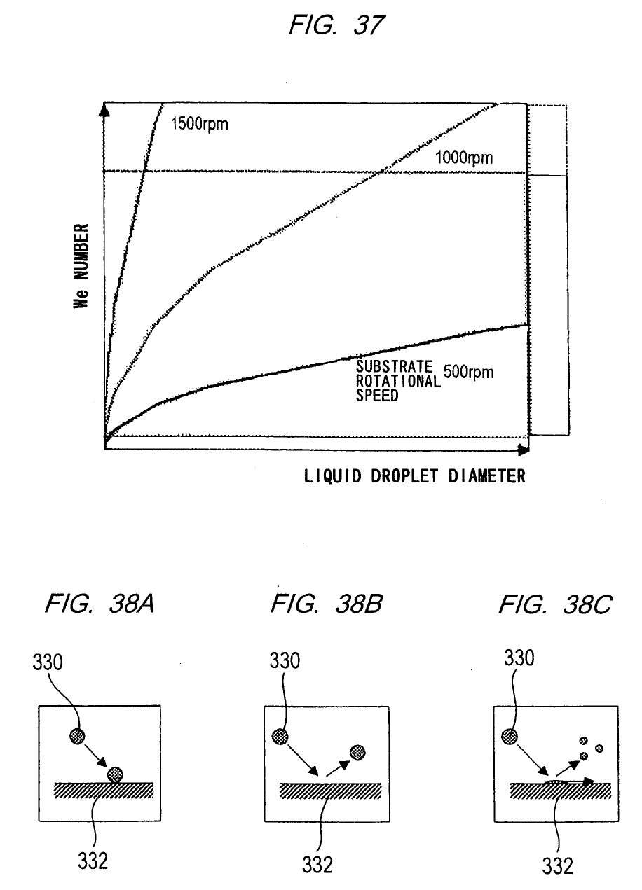

FIG. 37 shows the relationship between the liquid droplet diameter at the time a substrate wetted by a processing liquid is rotated at substrate rotational speeds of 500 rpm, 1000 rpm, and 1500 rpm, and the Weber number (We number). The Weber number (We number) is expressed by the following equation:
We number=ν\sqrt{ρd|δ}
(where ν: the liquid droplet speed, ρ: the liquid droplet density, d: the liquid droplet diameter, δ: the liquid droplet surface tension).

As the substrate rotational speed goes higher to 1500 rpm, the We number becomes larger, allowing minute liquid droplets to be easily broken, as shown in FIG. 38C. As the substrate rotational speed falls to 1000 rpm and 500 rpm, the We number becomes more difficult to increase, causing a liquid droplet 330 to change from a state in which it is reflected from an apparatus inner wall 332 or the like, as shown in FIG. 33B, to a state in which it tends to adhere to the apparatus inner wall 332 or the like, as shown in FIG. 33A. The lower-limit size of a liquid droplet that is broken up into a plurality of smaller liquid droplets is increased, i.e., there are less liquid droplets having a size corresponding to the breaking range, resulting in a reduced total number of liquid droplets that are broken up.

Therefore, while the substrate is being rotated at an initial rotational speed N₅ of 1000 rpm or less, or preferably 500 rpm or less, a dry gas of a low humidity is supplied into the processing chamber, if necessary, for initially drying the substrate, thus preventing liquid droplets from impinging upon the apparatus inner wall and broken up into smaller liquid droplets thereby to prevent a mist and humidity from increasing in the atmosphere.

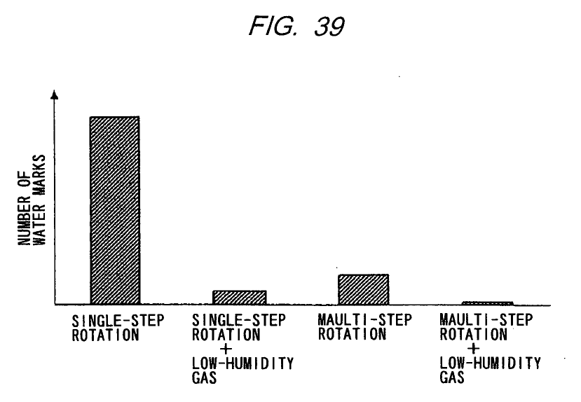

FIG. 39 shows the measured number of water marks on the surface of a silicon substrate having a diameter of 200 mm after the substrate is processed successively in the chemical liquid processing process, the cleaning process, and the drying process according to the substrate rotational speed profile shown in FIG. 35 (multi-step rotation), and the measured number of water marks on the surface of the substrate after the substrate is dried further in combination with the supply of a dry gas of a low humidity into the processing chamber (multi-step rotation+low-humidity gas). FIG. 39 also shows, as comparative data, the measured number of water marks on the surface of the substrate after the substrate is dried while it is being rotated in a single step (single-step rotation), and the measured number of water marks on the surface of the substrate after the substrate is dried further in combination with the supply of a dry gas of a low humidity into the processing chamber (single-step rotation+low-humidity gas).

As can be seen from FIG. 39, even when the substrate wetted by the processing liquid is processed at a constant rotational speed for being dried, the number of water marks is greatly reduced by supplying a dry gas of a low humidity. The number of water marks is also reduced by rotating the substrate in multiple steps (after most of the liquid on the substrate is removed at a low rotational speed, the rotational speed is increased to remove the residual liquid) without supplying a dry gas of a low humidity. If such multi-step rotation is combined with a low-humidity gas, the number of water marks is further reduced.

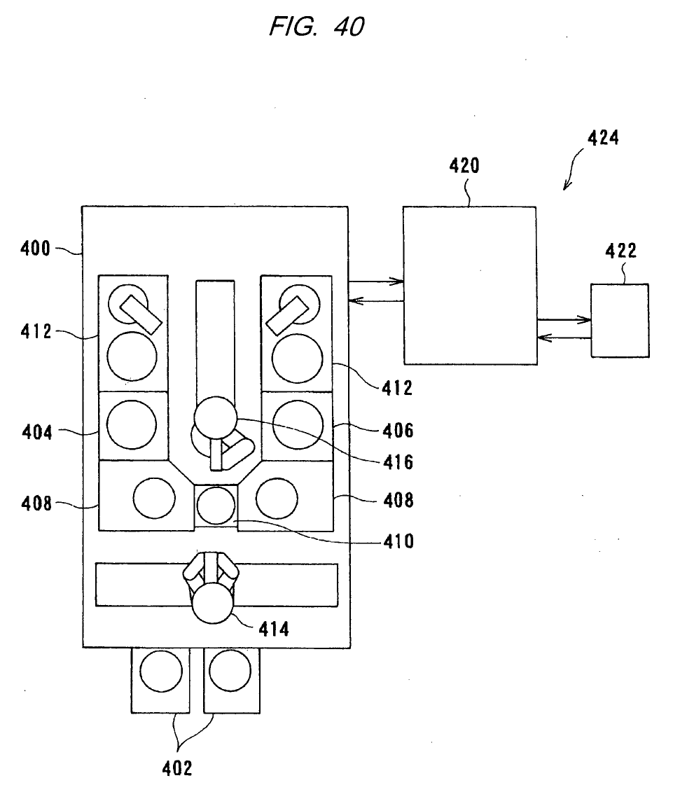

FIG. 40 shows an overall layout of a substrate processing apparatus (system) according to still another embodiment of the present invention. The substrate processing apparatus (system) has two loading/unloading units 402 for loading substrates into and unloading substrates from a main frame 400. The main frame 400 accommodates therein a heat treatment apparatus 404 for heat-treating (annealing) a plated film formed on the surface of a substrate, a bevel etching apparatus 406 for removing a plated film deposited on the peripheral edge of a substrate, four cleaning/drying apparatus 408 for cleaning the surface of a substrate with a cleaning liquid, such as pure water or the like, and spin-drying the substrate, a substrate stage 410 for temporarily placing a substrate thereon, and two plating apparatus 412. The main frame 400 also houses therein a movable first transfer robot 414 for transferring substrates between the loading/unloading unit 402 and the substrate stage 410, and a movable second transfer robot 416 for transferring substrates between the substrate stage 410, the heat treatment apparatus 404, the bevel etching apparatus 406, the cleaning/drying apparatuses 408, and the plating apparatuses 412.

The substrate processing apparatus having the structure shown in FIG. 34, for example, is used as at least one of the bevel etching apparatus 406, cleaning/drying apparatuses 408, and the plating apparatuses 412.

The main frame 400 is treated to make itself shielded against light for allowing various steps to be carried out in the main frame 400 in a light-shielded state, i.e., without exposing interconnects to light such as illuminating light or the like. Since interconnects are prevented from being exposed to light, interconnects made of copper, for example, are prevented from being exposed to light and developing an optical potential difference, and hence the interconnects are prevented from being corroded due to such an optical potential difference.

Furthermore, a plating solution management apparatus 424, which has a plating solution tank 420 and a plating solution analyzer 422, is positioned laterally of the main frame 400. The plating solution management apparatus 424 analyzes and manages the components of a plating solution used by the plating apparatuses 412, and supplies a plating solution of a predetermined composition to the plating apparatuses 412. The plating solution analyzer 422 has an organic material analysis section for analyzing an organic material by cyclic voltammetry (CVS), liquid chromatography, or the like, and an inorganic material analysis section for analyzing an inorganic material by neutralization titration, oxidation-reduction titration, polarography, electrometric titration, or the like. The analyzed results from the plating solution analyzer 422 are fed back to adjust the components of the plating solution in the plating solution tank 420. The plating solution management apparatus 424 may be incorporated in the main frame 400.

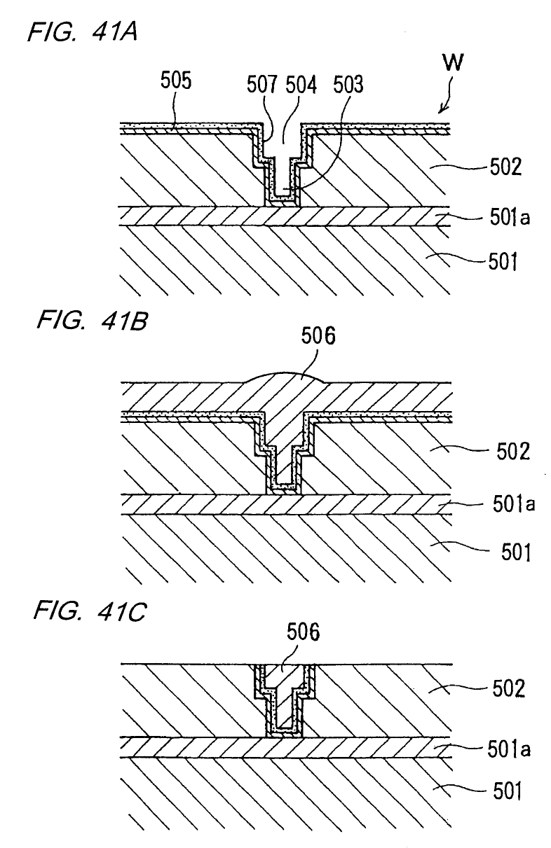

An example of a process of forming copper interconnects with the substrate processing apparatus (system) shown in FIG. 40 will be described below with reference to FIG. 41. As shown in FIG. 41A, an insulating film 502 made of SiO₂ is deposited on a conductive layer 501a on a semiconductor base 501 with a semiconductor device formed thereon. Fine recesses for interconnect, which comprise contact holes 503 and trenches 504, are formed in the insulating film 502 by performing lithography/etching technique. A barrier layer 505 made of TaN, TiN, or the like is formed on the surface, and a seed layer 507 as an electric supply layer for electroplating is formed on the barrier layer 505. In this manner, a substrate W is prepared. A substrate cassette housing the substrates W is placed on a loading/unloading unit 502.

One substrate is taken by the first transfer robot 414 out of the substrate cassette placed on the loading/unloading unit 402, and introduced into the main frame 400. The substrate is then transferred to and placed on the substrate stage 410. The second transfer robot 416 then transfers the substrate placed on the substrate stage 410 to either one of the plating apparatuses 412.

In the plating apparatus 412, a pre-plating treatment is first performed to apply a precoating or the like to the surface (to be processed) of the substrate, and thereafter the surface of the substrate is plated. Thus, as shown in FIG. 41B, contact holes 503 and trenches 504 in the substrate W are filled with copper, and a copper film 506 is deposited on the insulating film 502. At this time, the composition of the plating solution in the plating solution tank 520 is analyzed by the plating solution analyzer 422, and insufficient components are replenished with the plating solution in the plating solution tank 420, thereby supplying a plating solution having constant composition to the plating apparatus 412. After the plating process is finished, the plating solution remaining on the substrate is retrieved, and the plated surface of the substrate is rinsed. Thereafter, the surface of the substrate is cleaned with pure water or the like. The cleaned substrate is transferred to the bevel etching apparatus 406 by the second transfer robot 416.

In the bevel etching apparatus 406, the substrate is held and rotated horizontally, and the central area of the surface of the substrate is continuously supplied with an acid solution, and the peripheral edge of the surface of the substrate is continuously or intermittently supplied with an oxidizing agent solution. The acid solution may be a non-oxidizing acid, and fluoric acid, hydrochloric acid, sulfuric acid, citric acid, oxalic acid, or the like is used. As the oxidizing agent solution, one of an aqueous solution of ozone, an aqueous solution of hydrogen peroxide, an aqueous solution of nitric acid, and an aqueous solution of sodium hypochlorite is used, or a combination of these is used. The copper deposited on or adhering to the peripheral edge (bevel portion) of the substrate W is quickly oxidized by the oxidizing agent solution, and is simultaneously etched and dissolved away by the acid solution which is supplied from the central area of the substrate and spreads over the entire surface of the substrate.

At this time, an oxidizing agent solution and a silicon oxide film etching agent may be supplied simultaneously or alternately to the central portion of the backside of the substrate. Therefore, copper or the like adhering in a metal form to the backside of the substrate W can be oxidized with the oxidizing agent solution, together with silicon of the substrate, and can be etched and removed with the silicon oxide film etching agent.

The substrate whose bevel portion has been etched is transferred by the second transfer robot 416 to either one of the cleaning/drying apparatuses 408 in which the surface of the substrate is cleaned with a chemical liquid or cleaning water such as pure water or the like, and then spin-dried. The dried substrate is transferred to the heat treatment apparatus 404 by the second transfer robot 416.

In the heat treatment apparatus 404, the copper film 506 formed on the surface of the substrate W is heat-treated (annealed), thereby crystallizing the copper film 506 from which interconnects are to be formed. Specifically, the substrate is heated to 400° C., for example, and continuously heated for several tens to 60 seconds, after which the heating is finished. At the same time, if necessary, an oxidation prevention gas is introduced into the heat treatment apparatus 404 and caused flow along the surface of the substrate to prevent the surface of the copper film 506 from being oxidized. The substrate is heated generally to a temperature in the range from 100 to 600° C., preferably from 300 to 400° C.

The heat-treated substrate W is transferred by the second transfer robot 416 to the substrate stage 410 and held thereon. The substrate W held on the substrate stage 410 is then returned into the cassette on the loading/unloading unit 402 by the first transfer robot 414.

Thereafter, the extra metal and barrier layer formed on the insulating film 502 are removed by a chemical mechanical polishing (CMP) process or the like to planarize the surface of the substrate, thereby forming interconnects of the copper film 506 as shown in FIG. 41C.

In the above embodiment, the barrier layer is made of TaN, TiN, or the like, and the seed layer of copper. However, in addition to the above materials, Ti, V, Cr, Ni, Zr, Nb, Mo, Ta, Hf, W, Ru, Rh, Pd, Ag, Au, Pt, or Ir, or any of nitrides thereof may be employed.

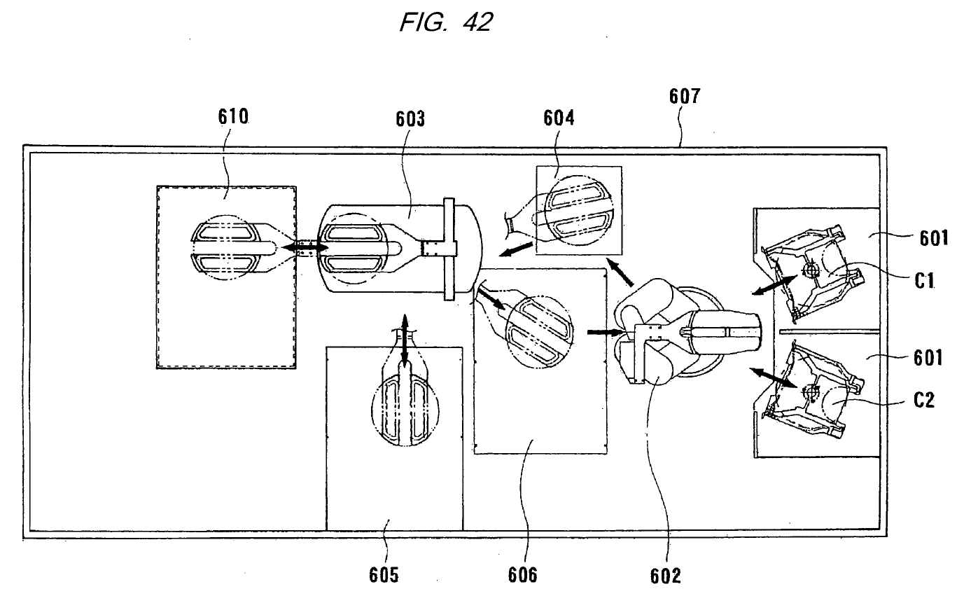

FIG. 42 is a plan view of an overall construction of a substrate processing apparatus (system) according to still another embodiment of the present invention. The substrate processing apparatus is adapted to polish the bevel portion, the edge portion, and the notch portion of a substrate such as a semiconductor wafer (Si wafer) or the like to remove surface irregularities on the peripheral edge, such as the bevel portion, the edge portion, and the notch portion, of the substrate and a film causing as a contaminant adhering to the peripheral edge of the substrate. After the peripheral edge is thus processed, the substrate is cleaned and unloaded from the substrate processing apparatus.

As shown in FIG. 42, the substrate processing apparatus (system) has a pair of loading/unloading stages 601 for placing substrate cassettes C1, C2, respectively, each housing a plurality of substrates such as semiconductor wafers or the like therein, a first transfer robot 602 for transferring a dry substrate, a second transfer robot 603 for transferring a wet substrate, a temporary placing table 604 for placing a semiconductor wafer which is to be processed or has been processed thereon, a polishing apparatus 610 for polishing the peripheral edge of a semiconductor wafer, and cleaning apparatuses 605, 606 for cleaning a polished semiconductor wafer. The first transfer robot 602 transfers a substrate between the cassettes C1, C2 on the loading/unloading stages 601, the temporary placing table 604, and the cleaning apparatus 606. The second transfer robot 603 transfers a substrate between the temporary placing table 604, the polishing apparatus 610, and the cleaning apparatuses 605, 606.

In this embodiment, the polishing apparatus 610 has a primary cleaning machine for performing primary cleaning on a substrate after the peripheral edge of the substrate is polished. Therefore, the cleaning apparatus 605 serves as a secondary cleaning machine for performing secondary cleaning on a substrate, and the cleaning apparatus 606 serves as a tertiary cleaning machine for performing tertiary cleaning on a substrate.

The substrate processing apparatus having the structure shown in FIG. 34, for example, is used as at least one of the polishing apparatus 610, the cleaning apparatus 605, and the cleaning apparatus 606.

The substrate processing apparatus shown in FIG. 42 is surrounded by a housing 607, and clean air is supplied to a lower air discharge section through a not-shown air supply fan, a chemical filter, an HEPA or ULPA filter disposed at the upper portion of the housing 607. A downward flow of clean air thus flows in the housing toward the surface of the substrate to prevent the substrate from being contaminated when the substrate is polished, cleaned, and transferred. A pressure gradient is provided in the substrate processing apparatus such that the pressure is progressively smaller in the loading/unloading stages 601, the temporary placing table 604 and the cleaning apparatus 606, the cleaning apparatus 605, and the polishing apparatus 610 in the order named. With this arrangement, even when the substrate processing apparatus is placed not only in a clean room, but also in an ordinary environment free of dust control, it serves as a dry-in/dry-out substrate peripheral edge polishing apparatus capable of performing a highly clean process.

A processing sequence of the substrate processing apparatus (system) having the structure shown in FIG. 42 will be described below.

The substrate cassettes C1, C2 housing substrates which have been processed in the CMP process and the copper film depositing process are transferred by a substrate transfer device (not shown) to the substrate processing apparatus, in which the substrate cassettes C1, C2 are placed on the loading/unloading stages 601. The first transfer robot 602 takes a substrate out of the substrate cassette C1 or C2 on one of the loading/unloading stages 601, and places the substrate on the temporary placing table 604. The second transfer robot 603 receives the substrate placed on the temporary placing table 604, and transfers the substrate to the polishing apparatus 610. In the polishing apparatus 610, the bevel portion, the edge portion, and the notch portion of the substrate are polished.

In the polishing apparatus 610, while the substrate is being polished or after the substrate is polished, pure water or a chemical liquid is supplied from one or more nozzles disposed above the substrate to clean the upper surface (including the bevel portion), the edge portion, and the notch portion of the substrate. The cleaning liquid is applied for the purpose of managing the material of the surface of the substrate (e.g., to form a uniform oxide film while avoiding modification such as irregular oxidization of the surface of the substrate with the chemical liquid) in the polishing apparatus 610. In addition, after the substrate is polished, a sponge roller is pressed against the peripheral edge of the substrate to scrub the peripheral edge. The cleaning process performed by the polishing apparatus 610 is referred to as primary cleaning.

The cleaning apparatus 605, 606 perform secondary cleaning and tertiary cleaning, respectively, on the substrate. The substrate which has been subjected to primary cleaning in the polishing apparatus 610 is transferred to the cleaning apparatus 605 or 606 by the second transfer robot 603. The substrate is subjected to secondary cleaning in the cleaning apparatus 605, or tertiary cleaning in the cleaning apparatus 606, or both secondary cleaning and tertiary cleaning in the cleaning apparatus 605 and the cleaning apparatus 606.

In the cleaning apparatus 605 or 606 where the substrate is finally cleaned, the substrate is dried. The first transfer robot 602 receives the dried substrate and returns it to the wafer cassette C1, C2 on the loading/unloading stage 601.

For the secondary cleaning and tertiary cleaning, contact-type cleaning (cleaning performed by a pencil-shaped or roll-shaped e.g., PVA sponge member) and contactless-type cleaning (cleaning performed by a cavitation jet or an ultrasonically vibrated liquid) may be combined with each other.

The polishing end point in the polishing apparatus 610 may be managed tabled on polishing time. Alternatively, the polishing end point may be detected by applying a light beam of a predetermined shape and intensity (such as a laser beam or an LED beam) from an optical means (not shown) to a region of the bevel portion where the polishing head is not positioned, in a normal direction to the device-forming surface of the substrate, and measuring scattering light from the region of the bevel portion to measure surface irregularities of the bevel portion.

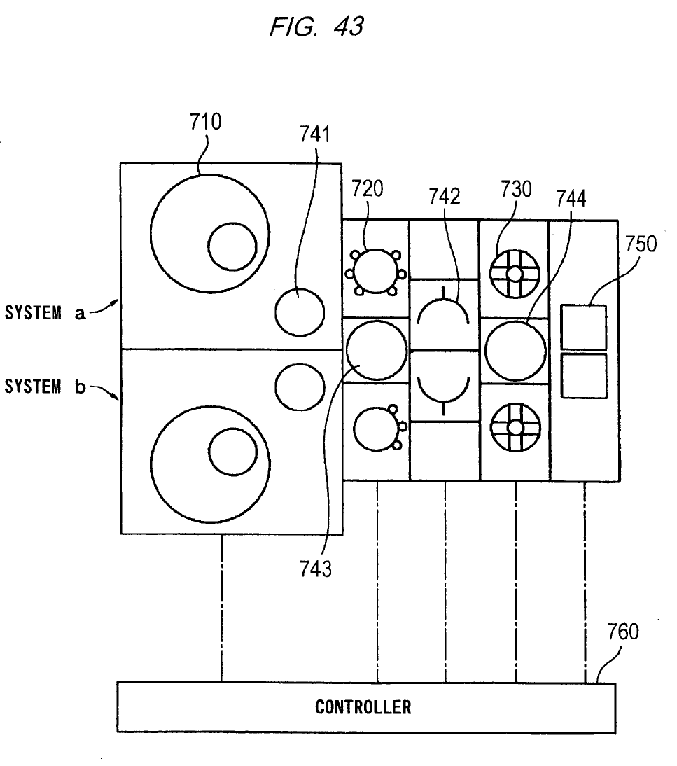

FIG. 43 shows a substrate processing apparatus (system) according to still another embodiment of the present invention. The substrate processing apparatus shown in FIG. 43 has two systems each having a polishing apparatus 710, a primary cleaning apparatus 720, and a secondary cleaning apparatus 730. The polishing apparatus 710, the primary cleaning apparatus 720, and the secondary cleaning apparatus 730 are installed in respective compartments defined by partitions, and air in the compartments is discharged independently of each other to keep their atmospheres out of interference with each other. Therefore, a mist or the like including a slurry in the polishing apparatus 710 does not adversely affect the primary cleaning apparatus 720 and the secondary cleaning apparatus 730, and a mist or the like containing a chemical liquid in the primary cleaning apparatus 720 does not adversely affect the secondary cleaning apparatus 730.

A transfer table 741 for temporarily placing a substrate 702 thereon is installed in each of the compartments housing the respective polishing apparatus 710. The primary cleaning apparatuses 720 are disposed adjacent to the compartments housing the respective polishing apparatus 710. A transfer machine 743 for transferring substrates is installed between the two primary cleaning apparatuses 720. Reversing machines 742 in the respective. systems for reversing substrates upside down are disposed adjacent to the primary cleaning apparatuses 720, and the secondary cleaning apparatuses 730 are disposed next to the reversing machines 742. A transfer machine 744 for transferring substrates is installed between the two secondary cleaning apparatuses 730. Loading/unloading units 750 for placing cassettes containing a plurality of substrates which are to be polished and cleaned or have been polished and cleaned are disposed adjacent to the secondary cleaning apparatus 730 and the transfer machine 744.

The substrate processing apparatus having the structure shown in FIG. 34, for example, is used as at least one of the polishing apparatuses 710, the primary cleaning apparatus 720, and the secondary cleaning apparatus 730.

A processing sequence of the substrate processing apparatus (system) having the structure shown in FIG. 43 will be described below.

A substrate which is taken out of one of the loading/unloading units 750 is reversed by one of the reversing machines 742 to face a surface thereof with an electric circuit incorporated therein downwardly. The substrate is then transferred to one of the polishing apparatuses 710. In the polishing apparatus 710, the substrate is polished (CMP) with a slurry to planarize the surface thereof with the electric circuit incorporated therein. The planarized substrate is transferred to one of the reversing machines 742, in which the substrate (to face the mirror surface thereof upwardly) reversed. The substrate is then transferred to one of the primary cleaning apparatuses 720, in which the surface of the substrate is scrubbed with a cleaning member while supplying a chemical liquid. The scrubbed substrate is transferred to one of the secondary cleaning apparatuses 730 by the transfer machine 734 or the transfer machine 744. In the secondary cleaning apparatus 730, secondary cleaning is performed by rotating the substrate and supplying DIW as a cleaning liquid, as shown in FIG. 35 described above, for example. Thereafter, the supply of DIW is stopped and the substrate is rotated at a maximum rotational speed to dry the substrate. The dried substrate is returned to the loading/unloading unit 750 by the transfer machine 744. Since the substrate processing apparatus shown in FIG. 43 has two systems of the polishing apparatus 710, the primary cleaning apparatus 720, and the secondary cleaning apparatus 730, two processes ranging from polishing to cleaning and drying operations can be performed parallel to each other.

The above operations are controlled by a controller 760. Though only main communications paths are shown in FIG. 43, the various apparatuses included in the substrate processing apparatus are connected to the controller 760 and operate according to signals from the controller 760. The controller 760 stores programs for the respective operations, and also stores speeds for the transferring operation of the transfer machines 743, 744, rotational speeds and cleaning times for the secondary cleaning operation, rotational speeds to be lowered in a former drying stage, and high rotational speeds for the drying operation of the secondary cleaning apparatus 730, for example. Since the controller 760 incorporates the operation programs, the above polishing, cleaning, and drying operations can easily be carried out.

Although certain preferred embodiments of the present invention have been shown and described in detail, it should be understood that various changes and modifications may be made therein without departing from the scope of the appended claims.

1. A substrate processing apparatus comprising:
a substrate holder for holding a substrate; and
a dry gas supply section for turning an atmosphere to which at least a portion of a surface of the substrate held by said substrate holder is exposed into a humidity-controlled dry gas atmosphere.

2. A substrate processing apparatus according to claim 1, wherein said dry gas supply section is adapted to apply and supply a humidity-controlled dry gas to at least a portion of a surface of the substrate held by said substrate holder.

3. A substrate processing apparatus according to claim 1, wherein said dry gas supply section is adapted to supply a dry gas comprising an inactive gas or air having a relative humidity controlled in the range from 0 to 30% into a processing chamber which accommodates said substrate holder therein.

4. A substrate processing apparatus according to claim 3, wherein said dry gas supply section is adapted to supply a dry gas into said processing chamber, in a volume which is 0.5 to 3 times the total volume of air that is discharged from said processing chamber when the dry gas is supplied from said dry gas supply section into said processing chamber.

5. A substrate processing apparatus comprising:
a polishing apparatus for polishing a thin film deposited on or adhering to a bevel or edge portion of a substrate; and
an etching apparatus for etching away a thin film remaining on the bevel or edge portion of the substrate which has been polished by said polishing apparatus.

6. A substrate processing apparatus according to claim 5, wherein at least one of said polishing apparatus and said etching apparatus comprises a substrate holder for holding a substrate, and a dry gas supply section for turning an atmosphere to which at least a portion of a surface of the substrate held by said substrate holder is exposed into a humidity-controlled dry gas atmosphere.

7. A substrate processing apparatus according to claim 5, further comprising:
a cleaning/drying apparatus for cleaning and drying the substrate whose bevel or edge portion has been etched by said etching apparatus;
wherein said cleaning/drying apparatus comprises a substrate holder for holding a substrate, and a dry gas supply section for turning an atmosphere to which at least a portion of a surface of the substrate held by said substrate holder is exposed into a humidity-controlled dry gas atmosphere.

8. A substrate processing method comprising:
polishing away a thin film deposited on or adhering to a bevel or edge portion of a substrate; and
etching away a thin film remaining on the bevel or edge portion of the substrate which has been polished.

9. A substrate processing method according to claim 8, comprising:
cleaning and drying the substrate in which the thin film remaining on the bevel or edge portion thereof has been etched away.

10. A substrate processing apparatus comprising:
a substrate holder for holding a substrate;
a monitor for monitoring the degree of drying of the substrate held by said substrate holder; and
a controller for controlling rotation of said substrate holder based on a monitor value outputted from said monitor and representing the degree of drying of the substrate.

11. A substrate processing apparatus according to claim 10, wherein said controller controls a rotational speed and/or rotational acceleration of said substrate holder.

12. A substrate processing apparatus according to claim 10, wherein said monitor comprises at least one of a mass meter for measuring a mass of liquid droplets scattered around from the substrate when the substrate is dried, a thermometer for measuring a temperature around the substrate, a mist amount measuring instrument for measuring an amount of mist around the substrate, a liquid droplet adhering area measuring mechanism for measuring an area of a liquid droplet adhering portion of the surface of the substrate, and a mass meter for measuring a mass of the substrate and the substrate holder, the arrangement being such that a measured value or a change in the measured value of at least one of the mass of liquid droplets, the humidity, the amount of mist, the area of the liquid droplet adhering portion of the surface of the substrate, and the mass of the substrate and the substrate holder is fed back to said controller to enable the controller to control the rotation of said substrate holder so that said measured value or the change in the measured value is equal to or less than a constant value.

13. A substrate processing apparatus comprising:
a substrate holder for holding a substrate; and
a controller for accelerating and decelerating a rotational speed of said substrate holder continuously or stepwise.

14. A substrate processing apparatus according to claim 13, wherein said controller increases the rotational speed of said substrate holder as a linear, quadratic, or higher-order function of a time that has elapsed from the start of drying the substrate at a rotational acceleration in the range from 0 to 300 rpm/s until the rotational speed of said substrate holder reaches a maximum rotational speed.

15. A substrate processing apparatus according to claim 13, wherein said controller changes the rotational speed of said substrate holder in n steps until the rotational speed of said substrate holder changes from an initial rotational speed at the start of drying the substrate to a maximum rotational speed, accelerates said substrate holder at a kth rotational acceleration until the rotational speed thereof changes from a (k-1)th (2≦k≦n) rotational speed to a kth rotational speed, makes the kth rotational speed greater than the (k-1)th rotational speed, and makes the kth rotational acceleration greater than a (k-1)th rotational acceleration.

16. A substrate processing apparatus according to claim 13, further comprising:
a drying unit for promoting the evaporation of a liquid adhering to the substrate held by said substrate holder; and
a controller for controlling said drying unit.

17. A substrate processing apparatus according to claim 16, further comprising:
a monitor for monitoring a humidity, a dew point, or a temperature in an atmosphere around the substrate held by said substrate holder, and sending a feedback signal to said controller.

18. A substrate processing method comprising:
holding a substrate with a substrate holder; and
rotating said substrate holder at a rotational speed which increases as a linear, quadratic, or higher-order function of a time that has elapsed from the start of drying the substrate at a rotational acceleration in the range from 0 to 300 rpm/s until the rotational speed of said substrate holder reaches a maximum rotational speed, thereby drying the substrate held by said substrate holder.

19. A substrate processing method comprising:
holding a substrate with a substrate holder; and
rotating said substrate holder at a rotational speed which changes in n steps until the rotational speed of said substrate holder changes from an initial rotational speed at the start of drying the substrate to a maximum rotational speed, accelerating said substrate holder at a kth rotational acceleration until the rotational speed thereof changes from a (k-1)th (2≦k≦n) rotational speed to a kth rotational speed, making the kth rotational speed greater than the (k-1)th rotational speed, and making the kth rotational acceleration greater than a (k-1)th rotational acceleration, thereby drying the substrate held by said substrate holder.
